(19) United States
(12) Patent Application Publication
(10) Pub. No.: US 2026/0057145 A1
(43) Pub. Date: Feb. 26, 2026

(54) AI-BASED STATE MANAGEMENT SYSTEM, METHOD, AND USER INTERFACE

(71) Applicant: PwC Product Sales LLC, New York, NY (US)

(72) Inventors: Joseph Kenneth LAW, Chicago, IL (US); Austin Thomas HUBER, South Dartmouth, MA (US); Kevin Barclay SMITH, River Forest, IL (US); Elias Antonio LUMER, New York, NY (US)

(73) Assignee: PwC Product Sales LLC, New York, NY (US)

(21) Appl. No.: 18/810,060

(22) Filed: Aug. 20, 2024

(51) Int. Cl. G06F 30/27

(52) U.S. Cl. CPC G06F 30/27

(57) ABSTRACT

A computer-implemented method is provided, the method comprising: storing, in memory of an AI-based state manager of an operating system, state transition instructions for transitioning states of the operating system; receiving, by an orchestrator of the AI-based state manager, an execution request; retrieving, by the orchestrator, from the memory, state transition instructions for an AI model of the AI-based state manager based on the execution request; providing, by the orchestrator, to the AI model, an AI model input comprising the retrieved state transition instructions; determining, by the AI model, an AI model output based on the AI model input; and applying, by the orchestrator, based at least in part on the AI model output, a state transition to the operating system by invoking one or more downstream systems.

### FIELD

This disclosure relates generally to the state management of operating systems, and more specifically, state management of operating systems by leveraging artificial intelligence.

### BACKGROUND

Abstraction in computing is the process of hiding the complex reality of a system by encapsulating complexity into layers, allowing developers and engineers to focus on higher-level problems without needing to understand the intricacies of lower levels. Starting with simple digital circuits, basic elements like transistors are abstracted into logic gates, which are then combined to create more complex components such as multiplexers, decoders, and arithmetic logic units (ALUs). These components are integrated into microarchitectures that implement instruction sets, enabling CPUs to execute a wide range of operations. The operating system further abstracts the hardware by managing resources and providing a platform for applications. Libraries and frameworks encapsulate higher-level functionality, enabling developers to create applications by focusing on user requirements and logic rather than the electrical signals and circuits at the foundation of the computational stack.

State management systems may operate in accordance with various automata theories. Through the modern automata theory, one can understand how combinational logic, FSMs, pushdown automata (PDAs), and Turing machines represent a hierarchy of computational models with increasing expressive power. Combinational logic forms the foundational building blocks of digital circuits, providing immediate outputs based on current inputs without memory. FSMs expand upon this by introducing a limited state-based memory, enabling the modeling of systems that require sequential logic and simple stateful computations. PDAs further extend FSMs by including an additional memory structure in the form of a stack, allowing for the recognition of context-free languages and the modeling of systems with nested structures or recursive patterns.

Finally, Turing machines sit at the top of this hierarchy, with an unlimited tape serving as memory, which grants them the capability to simulate any algorithmic process. This effectively encompasses the class of problems that can be computed algorithmically and represents the theoretical foundation for general-purpose computers. Each successive model subsumes the computational abilities of the previous, with Turing machines being the most powerful and general model, capable of expressing any computation that can be logically and mechanically performed. In traditional computer systems, state transitions of state machines are governed by digital logic and code, with FSMs and Turing machines serving as the primary models for managing these transitions.

Data flow control in traditional computer architecture helps to manage the movement of information between components such as the CPU, memory, and peripheral devices. This control is achieved through a combination of hardware mechanisms—like buses, registers, and control units—and software protocols implemented by operating systems and specialized programs. One particularly advantageous method within this framework is deterministic data routing throughout the computing stack. This approach offers several benefits, including enhanced predictability, efficiency, and reliability.

### SUMMARY

Expanding upon principles of abstraction and deterministic data routing techniques, provided herein is a state manager of an operating system with an embedded AI model, a computer-implemented method of state management using the AI model, and a user interface for configuring the same. In addition to an embedded AI model, the state manager may utilize an orchestrator and memory. The orchestrator may be used for managing user inputs, managing inputs and outputs to/from the AI model, pushing or pulling data to/from memory, and invoking downstream systems, including AI agents, teams of AI agents, and other operating systems at increasing levels of abstraction to perform complex tasks.

A user may deterministically configure instructions for managing state transitions and data routing to downstream systems via the user interface, and these instructions may be stored in memory. By embedding an AI model, such as a Large Language Model (LLM) within the state manager itself, a user may configure state transitions of the operating system using natural language, raw code, or any data type that an AI model has been trained to interpret and act upon. This allows for transition mechanisms to be made significantly more versatile and dynamic, providing a more human-like interaction with the system. The instructions stored in the memory can be leveraged by the orchestrator so that relevant information is provided to the AI model and downstream systems for performing their designated tasks.

Some current approaches to leveraging AI in system control pass all execution data to the AI model, resulting in irrelevant context being passed to the model which leads to reduced performance and speed and degrades output accuracy. These approaches lack the enhanced predictability, efficiency, and reliability of more deterministic approaches of data routing. For example, in a system that leverages several downstream systems in performing a task, neglecting a more deterministic approach can cause data that may be unnecessary for performing the system's designated task to be routed to the downstream system and/or can fail to provide the necessary data to perform their designated task. This can cause processing delays and inaccuracies and can reduce the predictability of system outputs. Thus, combining the versatility and flexibility of AI-based control systems with a more deterministic approach to data routing, as in the AI-based state manager and operating system described herein, can improve the speed, accuracy, and predictability of computing processes.

With respect to implementing AI into state managers of operating systems specifically, current approaches do not include an AI model within the state manager itself. Instead, current approaches merely “wrap” an AI model separately around an FSM. In these approaches, the FSM must programmatically parse the AI model's response to determine the next state of the operating system, as opposed to the AI model being able to determine the state transition on its own. In other existing implementations, the AI model would be sent all execution data, which decreases efficiency and limits the ability for the user to control state management. For example, a user would be unable to program state transitions using only natural language under these current approaches, and configuration of the state manager by the user is made less user-friendly.

These deficiencies are improved upon by the AI-based state manager, since instead of routing all execution data to the AI model, the AI model input is a combination of one or more downstream system outputs, transition options with transition criteria, the operating system goal, an optional user request, and a pre-set prompt template that are all selected by the orchestrator as being relevant in executing the requested task. Thus, the AI model is given the relevant context that it needs to determine the next state and receives less irrelevant information.

In some embodiments, a computer-implemented method is provided, comprising: storing, in memory of an AI-based state manager of an operating system, state transition instructions for transitioning states of the operating system; receiving, by an orchestrator of the AI-based state manager, an execution request; retrieving, by the orchestrator, from the memory, state transition instructions for an AI model of the AI-based state manager based on the execution request; providing, by the orchestrator, to the AI model, an AI model input comprising the retrieved state transition instructions; determining, by the AI model, an AI model output based on the AI model input; and applying, by the orchestrator, based at least in part on the AI model output, a state transition to the operating system by invoking one or more downstream systems.

In some embodiments, the AI model is a language model.

In some embodiments, the state transition instructions comprise natural language.

In some embodiments, the one or more downstream systems comprise one or more AI agents.

In some embodiments, each of the one or more AI agents are configured to perform a single task.

In some embodiments, the one or more AI agents comprise a planner agent team, and the computer-implemented method comprises generating a plan for carrying out the execution request by recursively invoking the planner agent team.

In some embodiments, the computer-implemented method further comprises searching, by the orchestrator, based at least in part on the execution request, a repository of tools to be employed by the one or more AI agents; retrieving, by the orchestrator, based at least in part on the execution request, a tool from the repository of tools; and routing, by the orchestrator, the tool to the one or more AI agents.

In some embodiments, the repository of tools comprises a vector database, and searching, by the orchestrator, based at least in part on the execution request comprises using a vector search algorithm.

In some embodiments, the repository of tools comprises a knowledge graph, and searching, by the orchestrator, based at least in part on the execution request comprises using a knowledge graph search algorithm.

In some embodiments, the one or more AI agents comprise one or more teams of AI agents.

In some embodiments, the one or more teams of AI agents comprise one or more sub-teams of AI agents.

In some embodiments, the computer-implemented method further comprises receiving, by the orchestrator, one or more outputs from the one or more downstream systems; and providing, by the orchestrator, to the AI model, an AI model input based at least in part on the one or more outputs from the one or more downstream systems.

In some embodiments, the one or more downstream systems are part of the AI-based operating system.

In some embodiments, the one or more downstream systems are part of a second AI-based operating system.

In some embodiments, a computer-implemented method for configuring an AI-based operating system is provided, comprising displaying an interface for configuring the AI-based operating system. In some embodiments, the interface comprises: one or more visual affordances, each representing an AI agent of the AI-based operating system, and a visual affordance for executing a program on the AI-based operating system; receiving, via the interface for configuring the AI-based operating system, a user selection of a visual affordance representing an AI agent of the AI-based operating system; displaying, in response to the user selection of the visual affordance representing the AI agent, an interface for configuring the AI agent; receiving, via the interface for configuring the AI agent, a user input comprising AI agent instructions and a selection of the visual affordance for executing a program by the AI-based operating system; configuring, by an orchestrator of the AI-based operating system, the AI agent based on the AI agent instructions; and executing, via the AI-based operating system, at least a portion of a program using the configured AI agent.

In some embodiments, the user input comprises one or more of an agent name, an agent type, or an agent version.

In some embodiments, the one or more visual affordances are displayed as a hierarchy of nodes, the hierarchy of nodes representing a team of AI agents of the AI-based operating system.

In some embodiments, each node represents an AI agent sub-team within the team of one or more AI agents.

In some embodiments, the nodes in the displayed hierarchy of nodes are connected by edges, each edge representing transition criteria for transitioning between AI agents.

In some embodiments, the interface for configuring the AI-based operating system comprises a visual affordance for configuring a transition between different AI agents, and the computer-implemented method comprises: receiving, via the interface for configuring the AI-based operating system, a user selection of the visual affordance for configuring the transition between different AI agents, displaying, in response to the user selection of the visual affordance for configuring the transition between different AI agents, a transition configuration interface; receiving, via the transition configuration interface, a user input comprising state transition instructions for transitioning between different AI agents; and generating, by the orchestrator, for an AI model of the AI-based operating system, an AI model input comprising the state transition instructions.

In some embodiments, the computer-implemented method comprises displaying, in response to receiving the selection of the visual affordance for executing a program by the AI-based operating system, a run interface comprising a log of AI agent activity and a list of active and completed program executions of the AI-based operating system.

In some embodiments, the interface for configuring the AI-based operating system comprises a visual affordance for adding an AI agent to the AI-based operating system.

In some embodiments, the AI agent instructions comprise natural language.

In some embodiments, a non-transitory computer-readable storage medium storing one or more programs is provided, the one or more programs comprising instructions which, when executed by a system comprising one or more processors and an operating system comprising an AI-based state manager, cause the system to: store, in memory of an AI-based state manager of an operating system, state transition instructions for transitioning states of the operating system; receive, by an orchestrator of the AI-based state manager, an execution request; retrieve, by the orchestrator, from the memory, state transition instructions for an AI model of the AI-based state manager based on the execution request; provide, by the orchestrator, to the AI model, an AI model input comprising the retrieved state transition instructions; determine, by the AI model, an AI model output based on the AI model input; and apply, by the orchestrator, based at least in part on the AI model output, a state transition to the operating system by invoking one or more downstream systems.

### BRIEF DESCRIPTION OF THE FIGURES

A better understanding of the features and advantages of the present disclosure will be obtained by reference to the following detailed description that sets forth illustrative embodiments, in which the principles of the disclosure are utilized, and the accompanying drawings of which:

FIG. 1 illustrates an AI operating system, according to some embodiments.

FIG. 2 illustrates a computer-implemented method, according to some embodiments.

FIG. 3 illustrates an AI operating system having a language state manager, according to some embodiments.

FIG. 4 illustrates an AI operating system leveraging AI agents, according to some embodiments.

FIG. 5 illustrates an AI operating system interacting with AI operating systems of sub-systems, according to some embodiments.

FIG. 6 illustrates an AI operating system interacting with AI operating systems of other systems, according to some embodiments.

FIG. 7 illustrates an AI agent, according to some embodiments.

FIG. 8 illustrates a repository of AI agent skills, according to some embodiments.

FIG. 9 illustrates a use case for an AI operating system, according to some embodiments.

FIG. 10 illustrates a use case for an AI operating system, according to some embodiments.

FIGS. 11-22 illustrate a user interface, according to some embodiments.

FIG. 23 illustrates a computer, according to some embodiments.

FIGS. 24-25 illustrate a use case for an AI operating system, according to some embodiments.

FIG. 26 illustrates the flow of information to, from, and within an AI operating system, according to some embodiments.

FIG. 27 illustrates a use case for AI agents of an AI operating system, according to some embodiments.

### DETAILED DESCRIPTION

Described herein are operating systems having AI-based state managers, user interfaces for configuring such operating systems, and computer-implemented methods of executing state transitions using such AI-based state managers. These operating systems, user interfaces, and computer-implemented methods may facilitate the use of AI agents, teams of AI agents, or other operating systems at increasing layers of abstraction, with each layer simplifying the operations of the layer below. The operating systems, user interfaces, and computer-implemented methods provided herein can enable a more intuitive, efficient, and powerful use of computing resources.

In some embodiments, an operating system having a state manager with an embedded AI model is provided. By including an AI model within the state manager, the AI model itself can be used to determine when to transition states of the operating system. This can allow for users to provide state transition instructions in any format that the AI model may be trained to recognize, improving the ease of customizing the operating system to perform complex tasks while allowing for more complex user inputs to be supported. Along with an embedded AI model, the AI state manager can include an orchestrator and memory. The orchestrator may be used to route the appropriate inputs to the AI model and/or one or more downstream systems, for example, one or more downstream AI agents. Through a user interface, a user may be able to configure the state transition criteria for transitioning between different downstream systems in a deterministic manner. These criteria, and other user instructions, may be stored in memory and leveraged by the orchestrator to deterministically route data to/from the AI model and subsystems of the operating system or other systems. This can help ensure that the AI model and the other systems have access to the most relevant information for performing their designated tasks, reducing uncertainty and improving efficiency.

In some embodiments, a computer-implemented method is provided, comprising storing, in memory of an AI-based state manager of an operating system, state transition instructions for transitioning states of the operating system. These state transition instructions may be optionally provided by a user of a user interface. The computer-implemented method may include receiving, by an orchestrator of the AI-based state manager, an execution request and retrieving, based on the execution request, state transition instructions from the memory. These instructions may be provided, by the orchestrator, to the AI model, as part of an AI model input. The AI model input may also include relevant outputs from downstream systems needed to execute the request. The computer-implemented method may involve determining, by the AI model, an AI model output based on the AI model input, where the AI model output may include a determination as to the next state of the operating system. The computer-implemented method may then include applying, by the orchestrator, based at least in part on the AI model's determination, a state transition to the operating system by invoking one or more downstream systems. For example, the AI model may determine an ID of a downstream system to be called next in executing the request, and it may output this ID to the orchestrator. The orchestrator may then apply the state transition by invoking the downstream system having that particular ID.

In some embodiments, a computer-implemented method is provided, which may involve displaying a user interface for configuring an AI-based operating system as described herein. The user interface may have an “edit” mode in which one or more visual affordances, each representing an AI agent of the AI-based operating system, can be displayed. The user interface may also have a “run” mode in which a visual affordance for executing a program on the AI-based operating system, along with a log of AI agent activity and a history of previous program executions, may be provided.

When the user interface is in the “edit” mode, the method may include receiving a user selection of a visual affordance representing an AI agent that they wish to edit. In response, an interface for configuring the AI agent may be displayed, including different fields for the user to configure various characteristics of the AI agent. A user may enter AI agent instructions into these fields, and the AI agent instructions may be stored in the memory of the AI-based state manager to be used by the orchestrator in invoking the AI agents. Upon receiving a user selection of the visual affordance for executing a program, one or more of the configured AI agents may be used to execute part or all of the execution request.

In the following description of the various embodiments, it is to be understood that the singular forms “a,” “an,” and “the” used in the following description are intended to include the plural forms as well, unless the context clearly indicates otherwise. It is also to be understood that the term “and/or” as used herein refers to and encompasses any and all possible combinations of one or more of the associated listed items. It is further to be understood that the terms “includes, “including,” “comprises,” and/or “comprising,” when used herein, specify the presence of stated features, integers, steps, operations, elements, components, and/or units but do not preclude the presence or addition of one or more other features, integers, steps, operations, elements, components, units, and/or groups thereof.

Certain aspects of the present disclosure include process steps and instructions described herein in the form of an algorithm. It should be noted that the process steps and instructions of the present disclosure could be embodied in software, firmware, or hardware and, when embodied in software, could be downloaded to reside on and be operated from different platforms used by a variety of operating systems. Unless specifically stated otherwise as apparent from the following discussion, it is appreciated that, throughout the description, discussions utilizing terms such as “processing,” “computing,” “calculating,” “determining,” “displaying,” “generating” or the like, refer to the action and processes of a computer system, or similar electronic computing device, that manipulates and transforms data represented as physical (electronic) quantities within the computer system memories or registers or other such information storage, transmission, or display devices.

The present disclosure in some embodiments also relates to a device for performing the operations herein. This device may be specially constructed for the required purposes, or it may comprise a general-purpose computer selectively activated or reconfigured by a computer program stored in the computer. Such a computer program may be stored in a non-transitory, computer readable storage medium, such as, but not limited to, any type of disk, including floppy disks, USB flash drives, external hard drives, optical disks, CD-ROMs, magnetic-optical disks, read-only memories (ROMs), random access memories (RAMs), EPROMs, EEPROMs, magnetic or optical cards, application specific integrated circuits (ASICs), or any type of media suitable for storing electronic instructions, and each connected to a computer system bus. Furthermore, the computing systems referred to in the specification may include a single processor or may be architectures employing multiple processor designs, such as for performing different functions or for increased computing capability. Suitable processors include central processing units (CPUs), graphical processing units (GPUs), field programmable gate arrays (FPGAs), and ASICs In some embodiments, the computing systems referred to in the specification may include cloud-based computing services such as Amazon EC2, Google Compute Engine, Microsoft Azure, and other Infrastructure-as-a-Service (IaaS), platform as a Service (PaaS), or Software as a Service (SaaS) platforms.

The methods, devices, and systems described herein are not inherently related to any particular computer or other apparatus. Various general-purpose systems may also be used with programs in accordance with the teachings herein, or it may prove convenient to construct a more specialized apparatus to perform the required method steps. The structure for a variety of these systems will appear from the description below. In addition, the present invention is not described with reference to any particular programming language. It will be appreciated that a variety of programming languages may be used to implement the teachings of the present disclosure as described herein.

An operating system having an AI-based state manager and related methods are first described, followed by an exemplary user interface for configuring the AI-based state manager and operating system.

### AI-based State Manager and Operating System

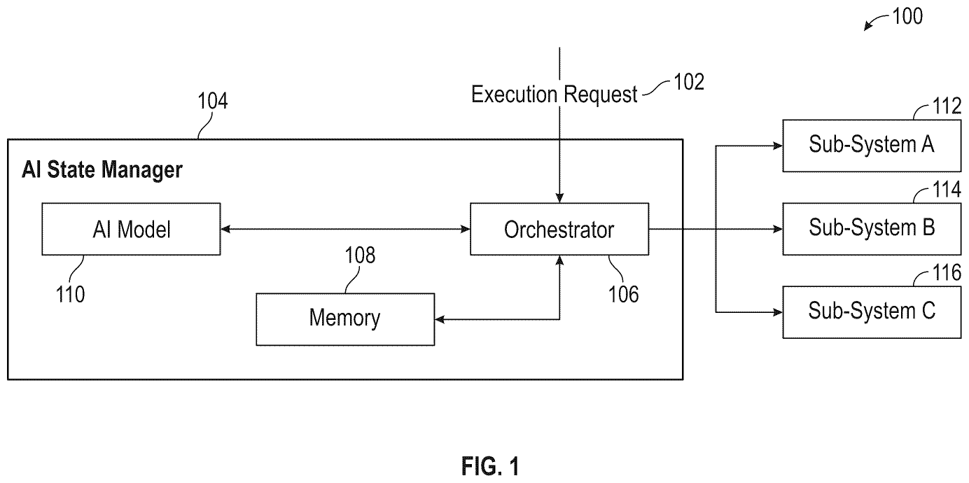

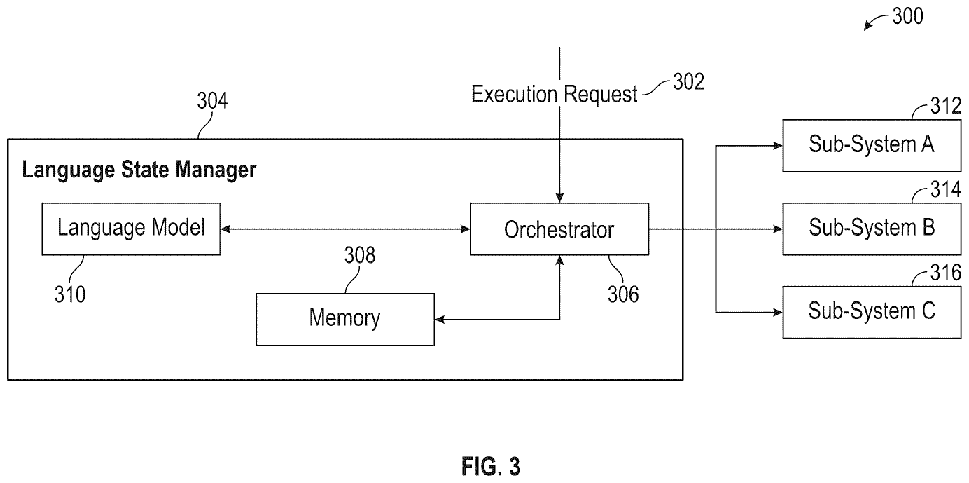

FIG. 1 provides a general example of an operating system 100 with an AI-based state manager 104 and various downstream systems 112, 114, 116, according to some embodiments. Since FIG. 1 illustrates a generalized instance of the operating system 100, the functionalities described with respect to this figure are applicable to higher abstraction layers of the operating system, which will be described with respect to FIGS. 3-6.

As shown, the AI-based state manager 104 can include an orchestrator 106, memory 108, and an embedded AI model 110. As used herein, “embedded” means that the AI model 110 is embedded within the logic of the state manager 104. The orchestrator 106 includes one or more parts of the state manager (e.g., one or more tools, platforms, or frameworks) that are specifically programmed to organize and automate the interactions between the embedded AI model 110 and downstream systems 112, 114, 116 of the operating system 100. Orchestrator 106 can be programmed specifically for use in the AI-based state manager 104 to invoke downstream systems using relevant data inputs, receive downstream outputs, dynamically build the AI model inputs at runtime, and invoke the AI model. One or more components of operating system 100 may be located on personal-use computers (e.g., phones, tablets, etc.), in an on-premises data center, and/or distributed over a cloud computing environment across different cloud servers (e.g., Amazon Web Services, Google Cloud Platform, Microsoft Azure, etc.). As such, it is to be understood that the components of the operating system 100 may interact with each other through calls to each component's application programming interface (API). For example, a downstream system 112, 114, 116 may be “invoked” by orchestrator 106 via a call to the system's API. Orchestrator 106 may also accept execution requests from other systems via a call to its API.

As shown in FIG. 1, the orchestrator may receive an execution request 102. Execution request 102 may take several different forms. In some embodiments, execution request 102 may include a request, given by the user in natural language, for a specific system to execute a program run. In some embodiments, execution request 102 may include an output or a request from another system to execute a program run. In specifying how a process is to be executed, the execution request 102 may include an operating system ID to be executed, which may be used to pull operating system information and instructions from the database. The execution request 102 may also include an input message, custom configuration parameter values that are injected during execution, and a parent process ID that can be used to track whether the request came from an upstream operating system.

The orchestrator 106 may execute a program run using information from the execution request 102, as well as operating system instructions that have been stored in memory of the state manager of the operating system. For example, operating system instructions stored in memory may specify which process/task to run and how the orchestrator 106 should route inputs and outputs in executing the desired process/task. These instructions may specify any downstream systems 112, 114, 116 that should be invoked by the orchestrator 106 to execute the program run and in which order. The operating system instructions may also specify the types of inputs and/or outputs that are relevant to systems 112, 114, 116 in performing their respective tasks. In some embodiments, the operating system instructions may be configured by a user of the operating system through a user interface, which will be described in detail in the next section. In this manner, the user can deterministically configure the flow of information from the orchestrator 106 through the operating system 100 prior to the receipt of execution request 102, improving the predictability of outputs and ensuring that systems of the operating system have the relevant inputs they need to perform a particular task.

The operating system instructions that are stored in memory and are configurable by the user prior to the program run may also include state transition instructions. As used herein, a “state” refers to a status of a process, computing resource, and/or a component of a system at any given time. State transition instructions may be configured by the user of the operating system via a user interface, as will be described. The orchestrator 106 may retrieve the state transition instructions from memory and may include them as part of the input to the AI model 110 based on the execution request. The state transition instructions may include various options of possible states of the operating system as well as criteria to be met in order to transition to each state option. AI model 110 may make state transition decisions by comparing the various outputs of downstream systems, etc. routed to it by the orchestrator to the state transition instructions that are configured by the user and stored in memory. Through this comparison, the AI model 110 can determine which state transition criteria for which state transition option(s) have been satisfied. The AI model 110 may then output its decision on the appropriate state for execution by the orchestrator in the form of a unique ID corresponding to the next system that is to be invoked by the orchestrator. In some embodiments, the orchestrator may execute a state transition by invoking the system specified by the AI model output (e.g., system 112, 114, 116), which may be internal to the operating system or an external system that may be needed to perform the next part of the program execution. Additionally, or alternatively, the state transition may be executed by running or terminating a process without invoking a downstream system 112, 114, 116. The downstream system can be another AI operating system, a non-AI software application, or any other downstream system that can be used to execute part or all of the program run.

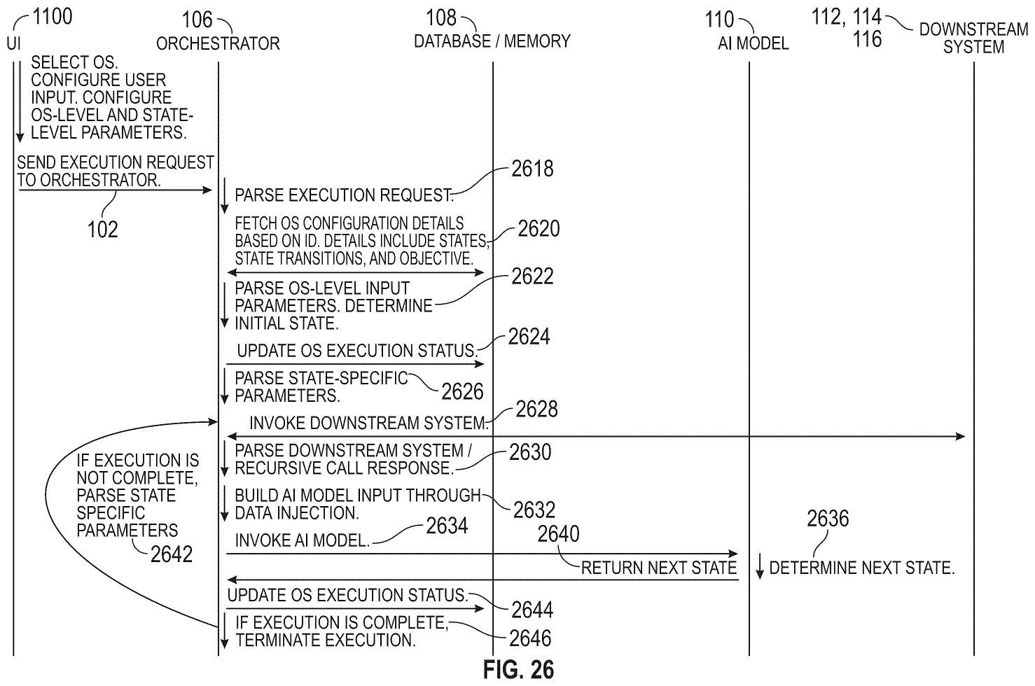

FIG. 26 illustrates a more detailed diagram showing the flow of information to, from, and within an operating system, according to some embodiments. At a user interface 1100, to be shown and described in detail in the next section, the user may be able to select an operating system that they would like to edit and/or use to run a program. The user may then configure operating system-level instructions (e.g., which system outputs will be relevant for the AI model in making the state transition decision) as well as the state-level instructions (e.g., the options for possible states and the criteria for the AI model to use in making the state transition decision). This information can be stored in memory 108 in the state manager.

An execution request 102 can be sent to the orchestrator 106, either by the user or by an outside system or subsystem. As described above, execution request 102 may include an operating system ID, an input message, custom configuration parameter values that are injected during execution, and a parent process ID. As shown at step 2618, the orchestrator 106 may parse this execution request and may fetch operating system instructions from the memory 108 based on the operating system ID at step 2620. The orchestrator 106 may set an initial state of the operating system by parsing the operating system-level input parameters at step 2622 and may update the operating system execution status to reflect the initial state at step 2624. At step 2626, the orchestrator 106 may parse state-specific parameters based on the initial state determination and may invoke a downstream system (112, 114, 116) at step 2628 to transition to the initial state of the operating system.

At step 2630, orchestrator 106 may parse the downstream system output or recursive call response from the initial state to determine the relevant output that the AI model will need to determine the next state of the operating system. The orchestrator 106 may then build, at step 2632, an AI model input which may include one or more downstream system outputs, transition options with transition criteria from memory 108, a downstream system/team goal, a user request, if any, and a pre-set prompt template for prompting the AI model. The pre-set prompt template may be engineered using principles of prompt engineering to ensure that the AI model output is a state of the operating system. For example, the prompt template may limit the AI model's output to be only the unique ID of the next agent to be selected, which can help ensure that the AI model returns its output in the correct format. The AI model input may be built by the orchestrator 106 using data injection by inserting the relevant downstream outputs, transition options and criteria, and objective into a prompt template, such that the AI model input contains relevant information for the AI model to make the state determination.

Data injection refers to the process of dynamically providing data to a system or application while it is running. In the context of the AI models described herein, text data may be injected into a prompt template by the orchestrator 106 by using information that 1) is only available at runtime (such as downstream system outputs) and/or 2) changes based on the current state of the system (such as the necessary inputs to a downstream system). This can allow the same prompt format to be used across executions while enabling the relevant context to be injected.

At step 2634, the orchestrator may invoke the AI model (e.g., by making an API call), and the AI model may decide the next state of the operating system based on the AI model input. The AI model may return its decision on the next state through an AI model output at step 2640, which may include the unique ID of the downstream system to invoke. The orchestrator then may update the operating system execution status at step 2644 to reflect the new state. If the execution of the program run is complete, the orchestrator may terminate the execution by switching to a “terminate” state at step 2646. If the execution of the program run is not complete, the orchestrator may also parse the state-specific parameters to build the relevant input request when invoking the downstream system, and the orchestrator may use this input while invoking the downstream system specified by the AI model output. Steps 2628-2644 may be repeated until the execution is determined to be complete.

In the example shown in FIG. 1, the AI model 110 may be any type of AI model suitable to perform a desired task (e.g., a language model, a neural network, and/or an anomaly detection model). FIG. 3 is an example of an operating system 300 in which the AI model 310 is a large language model (LLM), and thus, the state manager 304 is referred to as a language state manager. An advantage of embedding a language model within the state manager itself is that the execution request 302 and/or state transition instructions can be provided to the language model in natural language format. As such, the criteria for transitioning states of the operating system can be provided using natural language, which would not be supported by state managers that do not utilize a language model. Thus, more complex execution requests and state transition criteria can be provided to and executed by the language model (e.g., LLM 310), including state transition criteria that would have been impossible to implement in traditional FSMs.

In embodiments of operating system 300 having a language state manager 304, the AI model may support other input formats besides natural language, such that the user may still provide state transition criteria using traditional coding methods if they choose to do so. In some embodiments, AI model 110 (e.g., LLM 310) may be a generalized AI model, for example, a model that was not trained specifically for use in a state manager. Exemplary language models that may be used in an AI-based state manager include GPT-4, GPT-4o, Claude, and Google Gemini. In other embodiments, AI model 110 may be trained/fine-tuned to operate specifically within a state manager 104. In embodiments where the AI model is specialized for use in the state manager, an existing AI model can be fine-tuned with training data. This training data can include ground-truth input/output pairs. The input data may include a data-injected prompt from a prompt template explained above. The output data may be the desired output of the AI model, which is the state of the state manager that is to be associated with the particular data-injected prompt for training purposes. This process can be repeated, and the prompt template can be continuously refined to improve the accuracy of the AI model's state transition decision.

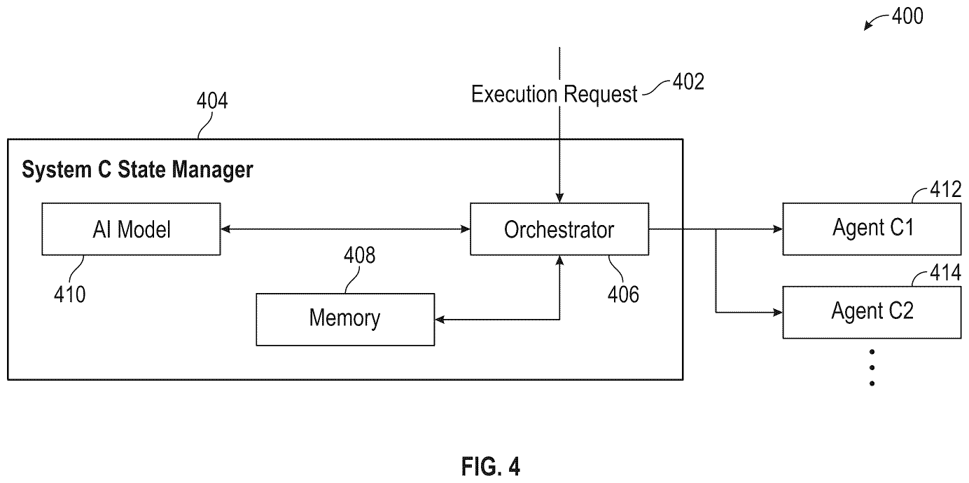

In FIGS. 1 and 3, the downstream systems 312, 314, 316 may be any subsystem of operating systems 100, 300 needed in executing the process specified by execution request 102, 302 such as traditional software tools or applications included in the application layer of a traditional computing stack. FIG. 4 provides an example of an operating system 400 operating at a higher level of abstraction than FIGS. 1 and 3, in which the downstream systems 412, 414 are AI agents specifically. Operating system 400 may be thought of as forming a new layer on top of the application layer in a traditional computing stack, where AI agents 412, 414 can interact with applications in the application layer below them.

As used herein, an AI agent is a system or program capable of autonomously performing tasks on behalf of a user, such as through autonomous interactions with other applications. In some embodiments, AI agents 412, 414 may be Azure Assistants, Autogen Agents, CrewAI Agents, and/or LangChain Agents. As shown in FIG. 4, orchestrator 406 may receive an execution request 402 for a program that is to be executed by operating system 400. The operating system instructions (optionally configured by the user) may also include instructions on which AI agents to invoke (e.g., make API calls to) in order to carry out different stages of the execution request. These instructions may be stored in memory 408 and leveraged by the orchestrator 406 once an execution request 402 is received. Further, state transition instructions, including criteria for transitioning states of the operating system and options of possible states, may be stored in memory 408 and leveraged by the orchestrator 406 in building the input for the AI model 410 to use in determining the next state of the state management system 404.

The input to the AI model 410 may include one or more downstream system outputs, transition options with transition criteria, an AI-based operating system goal, a pre-set prompt template, and optionally a user input. In this example, each different AI agent 412, 414, may represent a different “state” of the operating system, and as such, transitioning states of the operating system may involve transitioning from one AI agent to the next. Accordingly, based on the input provided by the orchestrator 406, the AI model 410 may determine whether the provided state transition criteria have been satisfied (e.g., whether the AI agent has fulfilled its role in the process). From this determination, the AI model 410 may provide an output to the orchestrator 406 including its decision on whether to transition states by calling upon the next AI agent in the process, specified by a unique ID of the next AI agent to be called. Orchestrator 406 may then carry out the state transition by invoking (e.g., making an API call to) the next AI agent based on the ID specified in the AI model's output.

In some embodiments, AI agents 412, 414 may be “simple” AI agents, meaning they are each configured to perform a single task. The AI agents 412, 414 may utilize (e.g., make API calls to) AI model 410, the same AI model embedded within state manager 404. AI agents 412, 414 may be configured, e.g., constrained, to perform a single task through the engineering of the prompts that each of the AI agents 412, 414 are allowed to use in performing their designated task. In some embodiments, prompt engineering can be performed by a developer writing a carefully crafted input to the AI agent to serve as a base message for how it should act. The language and syntax used in this prompt can govern the behavior of the AI agent. For example, a prompt can be written by a developer which contains goals, instructions, constraints, and guidance for how the AI agent should behave. Once executed, the behavior and output of the AI agent can be observed and the language inside its prompt can be modified to better align with the expected output.

One advantage of using “simple” AI agents is that inputs to each agent can be deterministically managed, and outputs from “simple” AI agents are more predictable and consistent. For example, a user may configure inputs to the “simple” AI agents through conventional coding methods and/or by using natural language. As such, inputs to AI agents can be routed by the orchestrator 406 in accordance with the user's instructions (e.g., configured through a user interface and/or stored in memory 408). This can help ensure that each agent has the proper context for carrying out their respective tasks while preventing them from being overwhelmed with irrelevant context. This contrasts from current systems, where the orchestrator typically passes all of the data from previous AI agent invocations into an AI agent input, providing too much data for the AI agent to process. Also, current systems typically rely on the AI model 410 alone to control which inputs and outputs the AI agents receive, leading to far more uncertain outcomes.

Another advantage of using “simple” AI agents is that they can be continuously abstracted into higher layers of complexity. For example, AI agents may be strung together in teams to perform complex tasks while keeping system outputs consistent and easy to analyze. Using teams of “simple” AI agents may aid in debugging and performance optimization since each agent's role in performing a task within the overall process is readily identifiable.

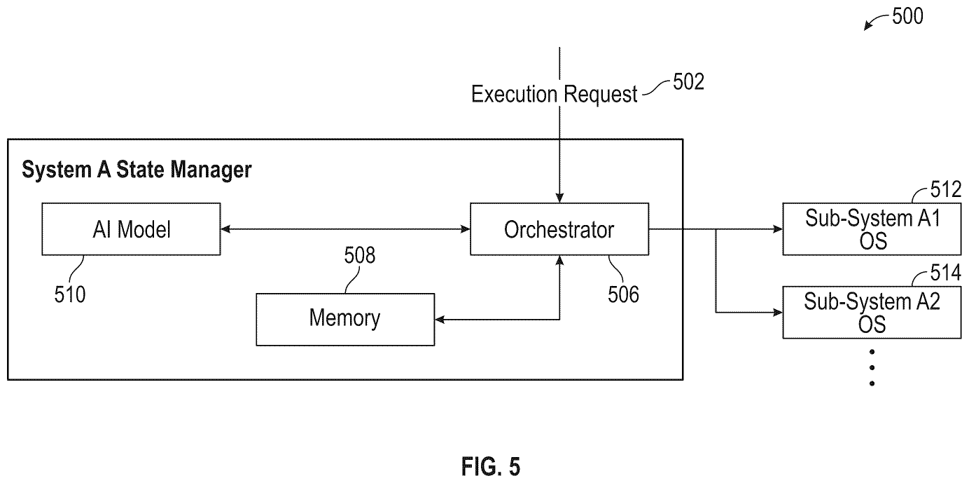

FIG. 5 shows the next highest level of abstraction, in which the operating system 500 can be composed of other operating systems 512, 514. These operating systems 512, 514, may have their own AI agents and/or teams of AI agents, and inputs and outputs may be deterministically routed to/from operating system 500 and operating systems 512, 514. As with FIG. 4, the orchestrator 506 may receive an execution request 502, and based on the execution request, orchestrator 506 may retrieve operating system instructions and state transition instructions from memory 508. Orchestrator 506 may inject an AI model prompt template with data from the operating system instructions and state transition instructions. The AI model 510 may determine which downstream operating systems to invoke, when to transition from one operating system to the next, and orchestrator 506 may then determine which inputs/outputs to route to/from AI agents across operating systems 512, 514.

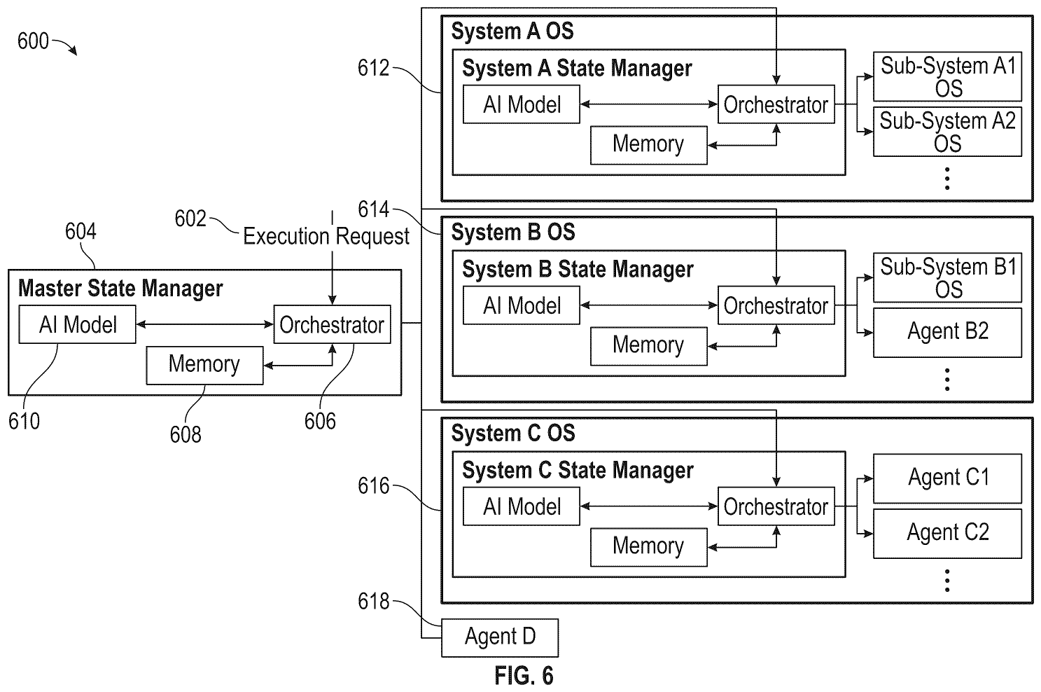

Similarly, FIG. 6 shows a higher level of abstraction, in which a master operating system 600 can invoke operating systems of external systems 612, 614, 616, as well as an AI agent 618 within the master operating system 600. The orchestrator 606 may communicate with the orchestrators of the other operating systems to route inputs and outputs and carry out state transitions. As in FIGS. 1 and 3-5, the execution request 602 may prompt the orchestrator 606 to retrieve operating system instructions and state transition instructions from memory 608. These instructions, along with relevant downstream system outputs and a pre-set prompt template, may be provided to the AI model 610 via the orchestrator 606. The AI model 610 may decide, based on the state transition instructions, which state the operating system 600 should transition to next and may output its decision to orchestrator 606 in the form of a unique ID of the next downstream system that the orchestrator should invoke. Orchestrator 606 may transition states by invoking the next AI agent, team of AI agents, and/or the next internal or external operating system specified by the AI model output. Additionally, the state management system 604 of master operating system 600 can manage multiple downstream operating systems simultaneously. In this sense, the example of FIG. 1 can be continuously abstracted into higher levels of complexity, supporting a vast number of processes that a user may want to execute across one or more AI-based operating systems.

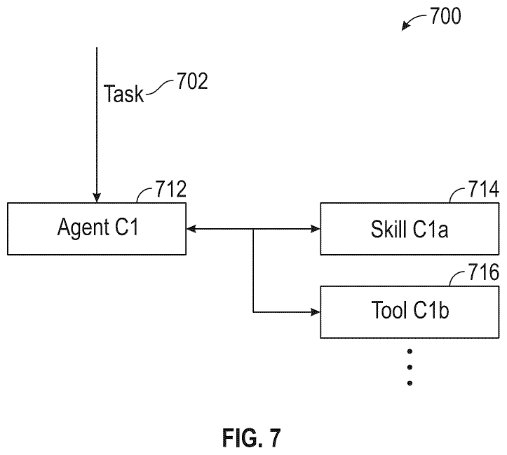

In some embodiments, as part of routing the relevant inputs to individual AI agents or teams of AI agents, the orchestrator of the operating system may be used to search for, and provide, the particular tools or skills an AI agent may need to perform a given task. For example, FIG. 7 shows a system 700 having an AI agent 712, according to some embodiments. The AI agent 712 can use one or more skills 714 and/or tools 716 to accomplish its task designated from execution instructions 702. As used herein, the words “skill” and “tool” are used interchangeably to refer to a snippet of code which an AI agent can autonomously execute to perform an action, resulting in an output that may then be returned to the AI agent. For example, an AI agent that interacts with a web application could have tools or skills that provide access to Python functions that enable it to write to and read from the application.

In some embodiments, each AI agent within the operating system may have its own knowledge base, or repository, of tools to be used in performing various tasks. The repository may include a broad array of potential tools that the AI agent may need to use, including tools that encompass functionalities that the AI model of the state manager was not originally trained upon. Toolshed knowledge bases provide agent-specific repositories of tools that can be configured to different approaches and techniques, providing agent-tool scalability, cost reduction, and latency reduction. The orchestrator of the operating system may be configured with various retrieval algorithms that allow it to identify and retrieve the most relevant tools for that an AI agent will need to perform a given task.

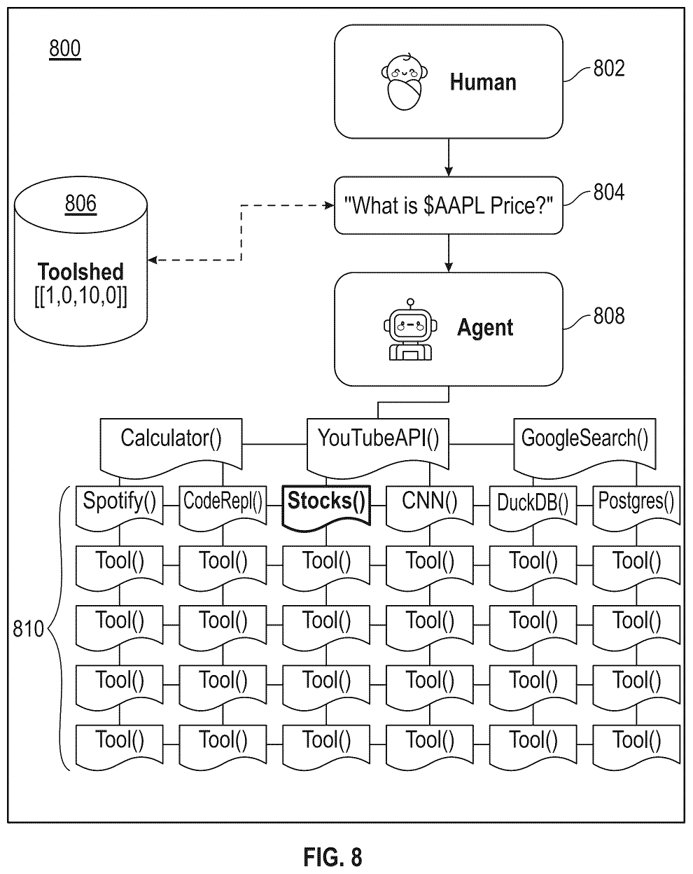

FIG. 8 illustrates an example of how the orchestrator may identify and retrieve relevant tools for an AI agent, according to some embodiments. As shown, a human user 802 may provide an input, which may be included as part of the execution request to the orchestrator.

From the execution request, the orchestrator of the operating system may determine that the goal 804 for the AI agent 808 will be to determine the price of a stock. The orchestrator of the operating system may use one or more retrieval algorithms to identify and retrieve the tools that the AI agent is most likely to need based on the assigned task 804. These tools may be retrieved from an agent-specific repository of tools, shown as toolshed 806. These toolshed knowledge bases can be configured with various unstructured search techniques, including vector databases and knowledge graphs. Additionally, the toolshed knowledge bases can employ different top k-values to retrieve the most relevant tools from each algorithm. Furthermore, the storage of tool details, such as the tool name, description, argument schema, and few-shot query examples, can be managed in various ways.

In some embodiments, toolshed 806 may be a vector database, and the orchestrator may use a vector search algorithm. Vector search algorithms include exhaustive k-nearest neighbors (KNN) and Hierarchical Navigable Small World (HNSW), among others, to find relevant matches of tools and score them based on similarity metrics such as cosine similarity, dot product, and Euclidian distance. The top-k values used to retrieve the most relevant skills can be optimized by factors such as retrieval accuracy, cost, and latency.

In some embodiments, toolshed 806 may be a knowledge graph, and the orchestrator may use a knowledge graph search algorithm. Knowledge graph search algorithms and implementations typically include cypher queries for graph exploration, semantic search, pattern matching, shortest path algorithms, graph neural networks, and embedding techniques to structure and retrieve interconnected information effectively in Retrieval-Augmented Generation (RAG) systems. The top-k values to retrieve the most relevant tools may be optimized by factors such as retrieval accuracy, costs, and latency.

Once the orchestrator has probabilistically determined which tools the AI agent 808 is most likely to need to perform a given task, these tools 812 may be routed to the AI agent 808. As shown, the “Stocks” tool was retrieved from toolshed 806 by the orchestrator as being one of the most relevant tools the AI agent 808 may need. The AI agent 808 may now invoke the “Stocks” tool to perform its designated goal 804. The storage and probabilistic retrieval of tools to be used by AI agents of the operating system can reduce latency by eliminating unnecessary routing and ensuring that only essential tools are provided to the AI agent. Additionally, this approach may minimize costs by economizing on token usage during execution of the AI agents. This approach thus promotes the development of highly optimized and robust tool-equipped agents. When integrated into AI operating systems, these adapted agents contribute to a well-coordinated and efficient AI-driven workflow, facilitating enhanced multi-agent collaboration and overall system scalability and functionality. The probabilistic approach to routing tools to AI agents allows the operating system to adapt to the complexities of high-level tasks while maintaining deterministic flow control and optimal performance.

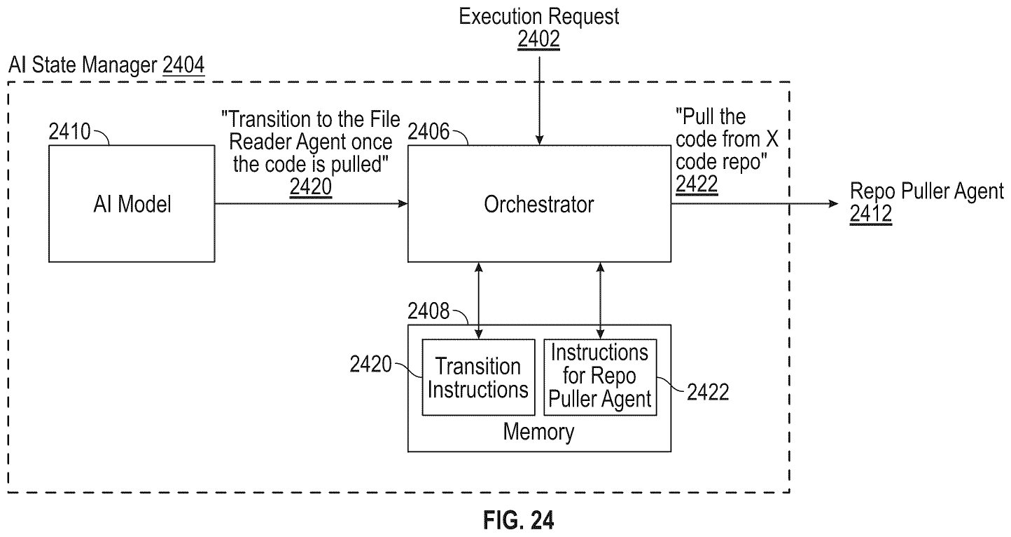

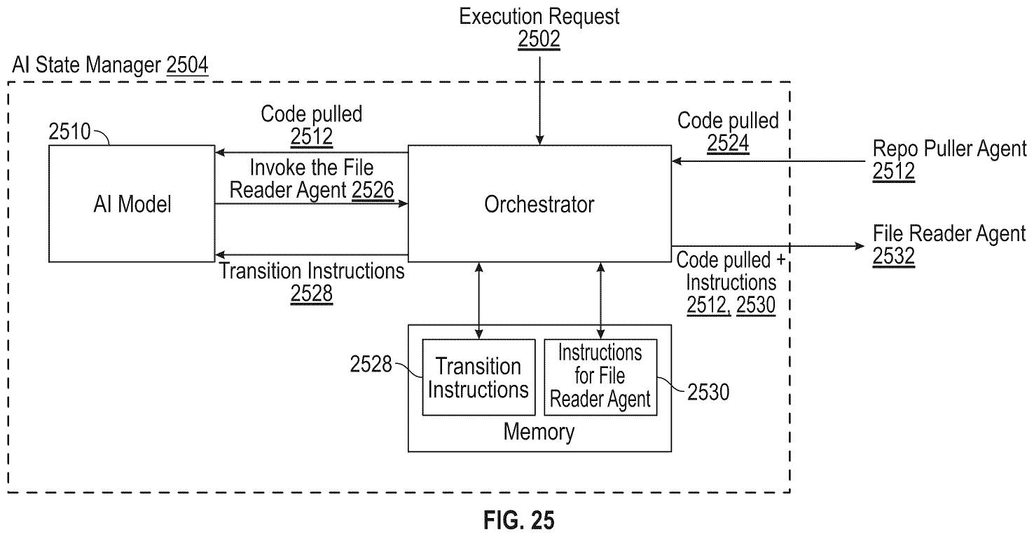

Using the principles of abstraction described herein, layered AI-based operating systems can be leveraged in mobile devices, personal computers, computer networks, and enterprise systems. To further illustrate the capabilities of layered operating systems having AI-based state managers, various exemplary use cases will now be described. FIGS. 24 and 25 illustrate a simple use case, in which the task necessitated by execution request 2402 involves translating code from a first language to a second language. Starting with FIG. 24, the execution request 2402 is received via orchestrator 2406 of the AI state manager 2404. In this example, the task necessitated by the execution request is translating code from a first language to a second language. Based on the task at hand, orchestrator 2406 may retrieve instructions from memory 2408 and route them to the AI model 2410 and an AI agent 2412 for performing the given task. Some of these instructions (2422) may be instructions for an AI agent, called a “repo puller” 2412, to pull code from a particular code repository to begin the translation process. Transition instructions 2420, including criteria that must be met to transition from the repo puller agent 2412 to the next AI agent, may be provided to the AI model 2410 by the orchestrator 2406. As described above, the transition instructions 2420 and instructions for the AI agent 2422 may be configured by the user using natural language and may be stored in memory 2408 prior to the execution request being received by the orchestrator 2406.

Building on FIG. 24, FIG. 25 illustrates that the repo puller agent 2412 has now provided an output 2524 to the orchestrator 2406 containing the code that it pulled from the code repository. The orchestrator 2406 may determine that this output 2524 is relevant to the AI model 2410 in determining whether the state transition criteria have been satisfied. Thus, output 2524 is routed by the orchestrator 2406 to the AI model 2410 as part of the AI model input.

Based on the transition criteria 2420 provided to the AI model 2410 back in FIG. 24, which said to “transition to the file reader agent once the code is pulled,” AI model 2410 may determine that the state transition criteria of pulling the code has been satisfied. Accordingly, the AI model 2410 may output the next state 2526 to the orchestrator 2406, which may tell the orchestrator to invoke the downstream system defined by the unique ID (which, in this example, would be the file reader agent's unique ID). Although not shown in FIG. 24, the AI model's instructions 2526 may be stored in memory 2408 and then retrieved by the orchestrator 2406.

The orchestrator may then invoke file reader agent 2532 by making a call to the file reader agent's API. In addition, the orchestrator may retrieve instructions for the file reader agent 2530 from memory 2408 that it determines are relevant for the file reader agent 2532 in performing its designated task. The orchestrator 2406 may also determine that the repo puller agent's output 2524 containing the code pulled from the code repository is relevant for the file reader agent 2532 to perform its designated task. Accordingly, instructions 2530 and output 2524 may both be routed by the orchestrator 2406 to the file reader agent 2532. The orchestrator 2406 may retrieve the next set of transition instructions 2528 from memory 2408 and may route these to the AI model 2408 so that the AI model can decide to transition from file reader agent 2532 to the next agent in line.

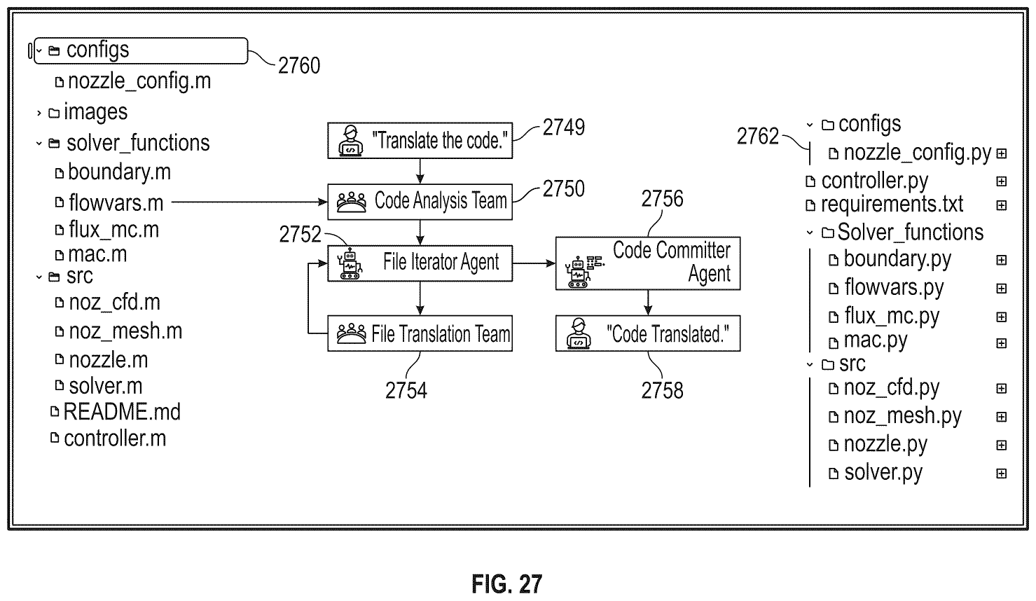

FIG. 27 demonstrates how a combination of individual AI agents as well as teams of AI agents may be invoked in carrying out an execution request using an AI-based operating system. Continuing from the example of FIGS. 24 and 25, FIG. 27 shows an AI-based operating system input that is received in the form of an execution request 2749. The execution request 2749 entails translating code from a first language to a second language. In this example, the first language is MATLAB, and the second language is Python. The MATLAB files to be translated are shown on the left at 2760.

The repo puller agent 2412, described above, may be part of a code analysis team 2750. The code analysis team 2750 may also include a dependency analysis agent to determine a dependency graph of the files pulled from the code repository as well as a file order agent to determine the order in which the files should be translated based on their dependencies. As shown in FIG. 27, the output(s) from the code analysis team 2740 (e.g., the order in which files should be translated) may be passed to the file iterator agent 2752, which may then provide the files to a file translation team 2754 in the order specified by the code analysis team output.

The file translation team 2754 may include the file reader agent 2532, described above. The file reader agent may read the files pulled from the code repository and send the read code to a code translator agent of the file translation team 2754, which may be configured to translate the code from the first language to a second language. The translated code may be passed to a code validation agent, team, or sub-team within the file translation team 2754, which can check the translated code against the source code for mistakes. If mistakes are detected, a code fixer agent, team, or sub-team within file translation team 2754 can correct them. Once mistakes are corrected and/or no mistakes are detected, the translated code may be routed to a file writer agent, which may write the code in a file and store the file within a folder based on the initial dependency graph provided by the code dependency team, as shown by the list of translated Python files 2762 in FIG. 27. These steps may be repeated until all of the code repository has been translated. Once all of the MATLAB files have been translated to Python, the translated files may be sent to a code committer agent 2756. The code committer agent 2756 may then commit the code files to a code repository, such as GitHub. At this point, an AI-based operating system output 2758 indicating that the code has been translated may be provided to the orchestrator of the state manager, where it may be used to generate the next AI model input for determining the next state of the AI-based operating system.

Although each of the AI agents and teams are shown as being sequentially invoked in the example shown in FIGS. 24-25 and FIG. 27, in some embodiments, more than one AI agent may be performing its designated task at a given time. In this sense, it is possible to have multiple states of the operating system (e.g., multiple AI agents, AI agent teams, or operating systems) running in parallel, and the state management system may invoke and/or manage multiple downstream systems concurrently.

Types of foundational AI agents include planner, validator, generator, tester, runner, and fixer agents. All agents can have associated tools (e.g., skills) that may be needed to complete a task. Runner agents carry out specific actions on behalf of the operating system, such as writing to a file, etc. The repo puller agent 2412 and the file reader agent 2532 in FIGS. 24-25 are examples of runner agents. Planner agents may develop a plan outlining the flow of any steps, tools, or skills that are needed to perform a task necessitated by the execution request. Planner agents and/or teams can be recursively called until a plan has enough detail to be carried out. Validator agents may use logic and reasoning to determine if a previous agent/team output is valid and if it accomplishes the specified goal while adhering to the relevant constraints. review the outputs of other AI agents for accuracy. Generator agents may create net new content. Tester agents may execute tools (e.g., skills) to validate some functionality. These foundational AI agents can be assembled into teams and/or sub-teams to perform a given task in addition to being capable of performing tasks individually.

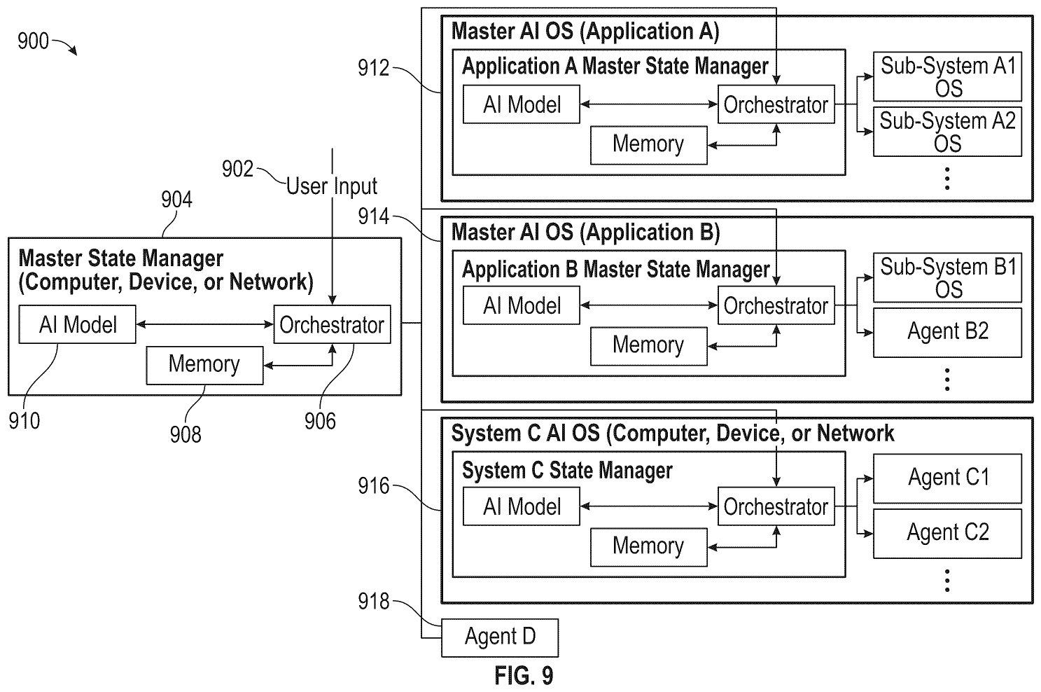

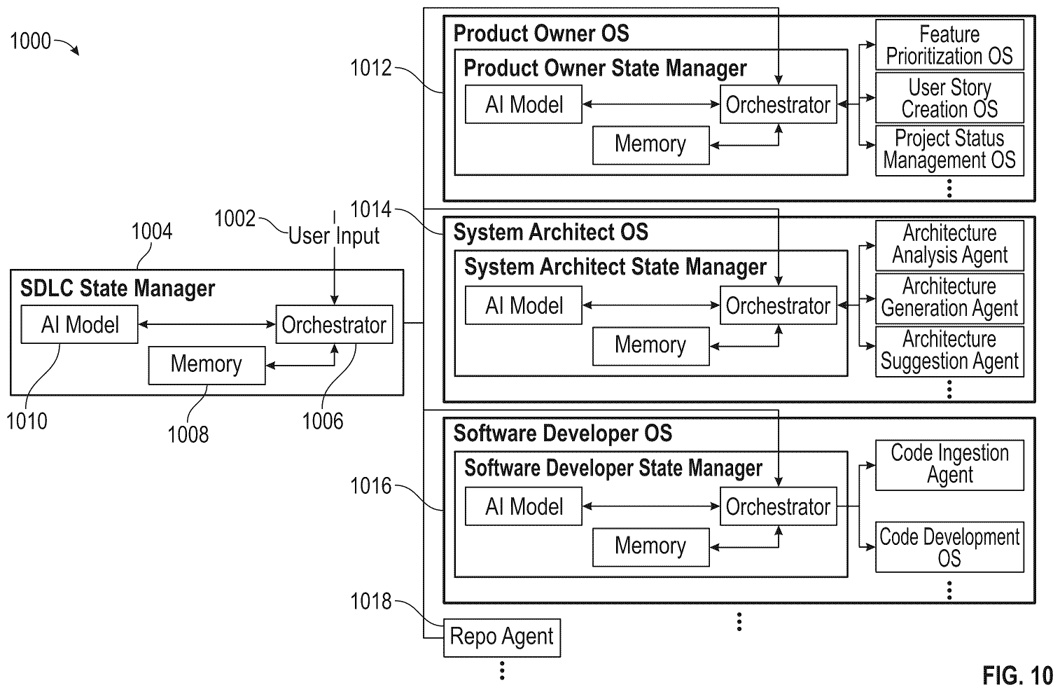

FIGS. 9 and 10 illustrate exemplary use cases of operating systems having AI-based state managers at higher levels of abstraction. For example, FIG. 9 illustrates how developers may use master AI-based operating systems for their applications 912, 914, 916, which can then be invoked through a master AI-based state manager 904 of a device, computer, or network. FIG. 10 depicts a possible enterprise use case for an AI-based operating system in automating various parts of a software development lifecycle (SDLC). For example, various AI-based operating systems may carry out tasks typically performed by certain professionals in the SDLC, such as a product owner operating system 1012, a system architect operating system 1014, a software developer operating system 1016, along with one or more AI agents 1018. Operating systems 1012, 1014, and 1016, and agent 1018, may be controlled through the master SDLC state manager 1004. As shown in FIGS. 9 and 10, in embodiments involving multiple operating systems, the orchestrator of the master state manager may invoke the other operating systems by calling upon their respective orchestrators.

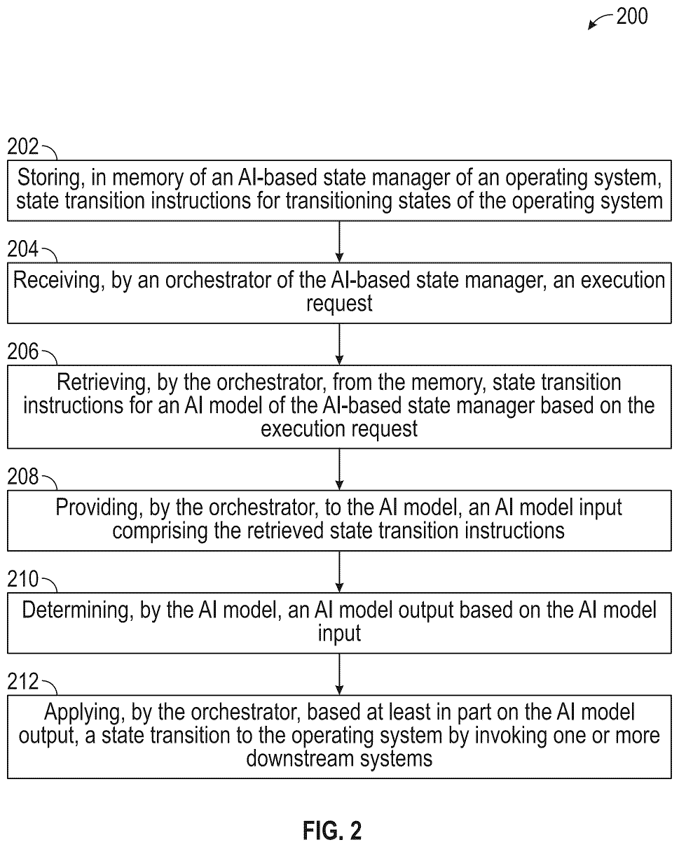

FIG. 2 illustrates a computer-implemented method 200 summarizing the functionalities of the AI-based state managers and operating systems described herein. At step 202, the method may include storing, in memory of an AI-based state manager of an operating system, state transition instructions for transitioning states of the operating system. As described above, the state transition instructions may optionally be received from a user through a user interface. Step 204 may include receiving, by an orchestrator of the AI-based state manager, an execution request. For example, the execution request may be generated from a user pressing a “run” button on the user interface, or it may be from another system making a request of the orchestrator of the AI-based operating system. Based on the execution request, e.g. based on the ID of the process to invoke included within the execution request, the goal included within the execution request, and/or the types of processes and tasks needed to be run in performing the execution request, the orchestrator may retrieve state transition instructions from the memory at step 206.

The orchestrator may also retrieve outputs from downstream systems that it determines to be relevant for an AI model of the operating system to use in determining the next state of the operating system. The orchestrator may generate an AI model input by injecting the retrieved state transition instructions and downstream system outputs into a prompt template, and the orchestrator may provide this input to the AI model at step 208. Based on the AI model input, e.g. by comparing state transition options and the criteria for each that may be specified in the state transition instructions, the AI model may make a determination as to whether the state of the operating system should be changed, and if so, which downstream system should be invoked at step 210. The AI model may provide this determination as an output including a unique ID of the downstream system to be invoked by the orchestrator. The orchestrator may then apply the state transition by invoking (e.g., making an API call to) the downstream system specified by the unique ID in the AI model output at step 212.

### User Interface

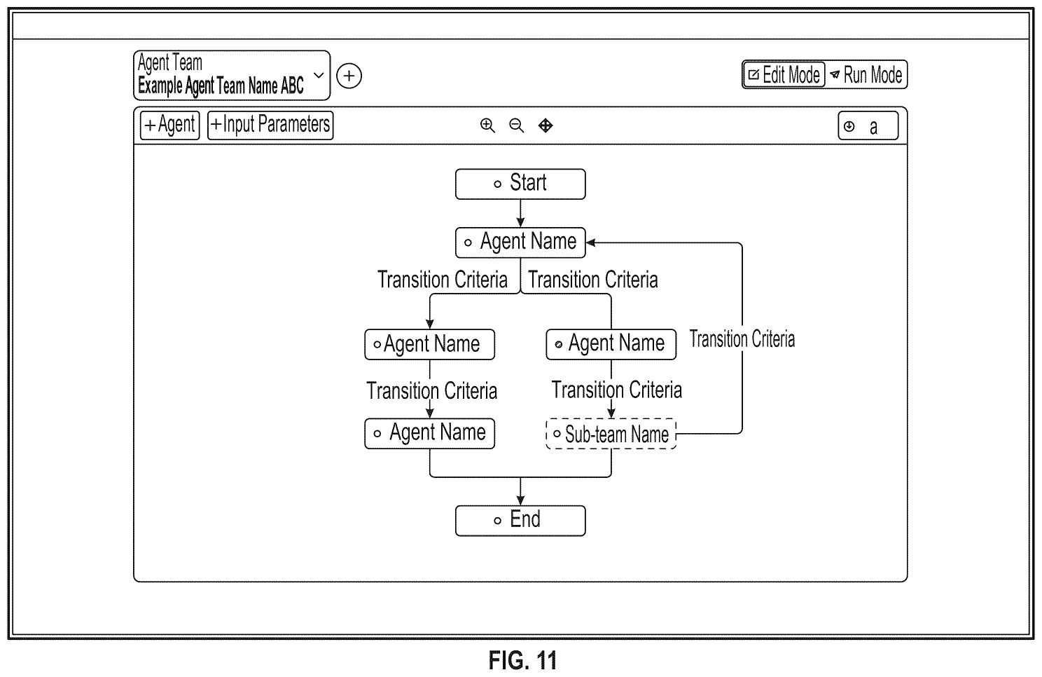

As described in the previous section, one advantage of embedding an LLM within a state manager of an operating system is that a user may be able to input operating system instructions and state transition instructions using natural language inputs. Accordingly, the backend process of configuring the AI-based state manager and operating system is made much more user-friendly, making the AI-based state manager and operating system particularly suited for configuration through a user interface. FIGS. 11-22 illustrate various views of an exemplary user interface that can be used to configure the operating system instructions (e.g., instructions for AI agents of the operation system) and state transition instructions for use by the orchestrator and AI model in determining and executing state transitions, according to some embodiments.

Beginning with FIG. 11, the exemplary user interface is shown in an “edit” mode, in which a visual affordance for selecting the edit mode, along with a visual affordance for switching to a “run” mode, are shown in the top-right corner. In some embodiments, the user interface may automatically display the edit mode upon the user initializing the user interface.

The edit mode may allow a user to configure one or more AI agents or teams of AI agents of the operating system. As shown in FIG. 11, the user interface may be a graph-based user interface in which each agent or sub-agent team is shown as a node in the graph. The nodes may be arranged in a hierarchy illustrating the process flow, with the nodes being connected by edges representing state transitions between each node. There may also be a “start” node and an “end” node that may be automatically or manually added to the graph for configuring the initial and final states of the operating system.

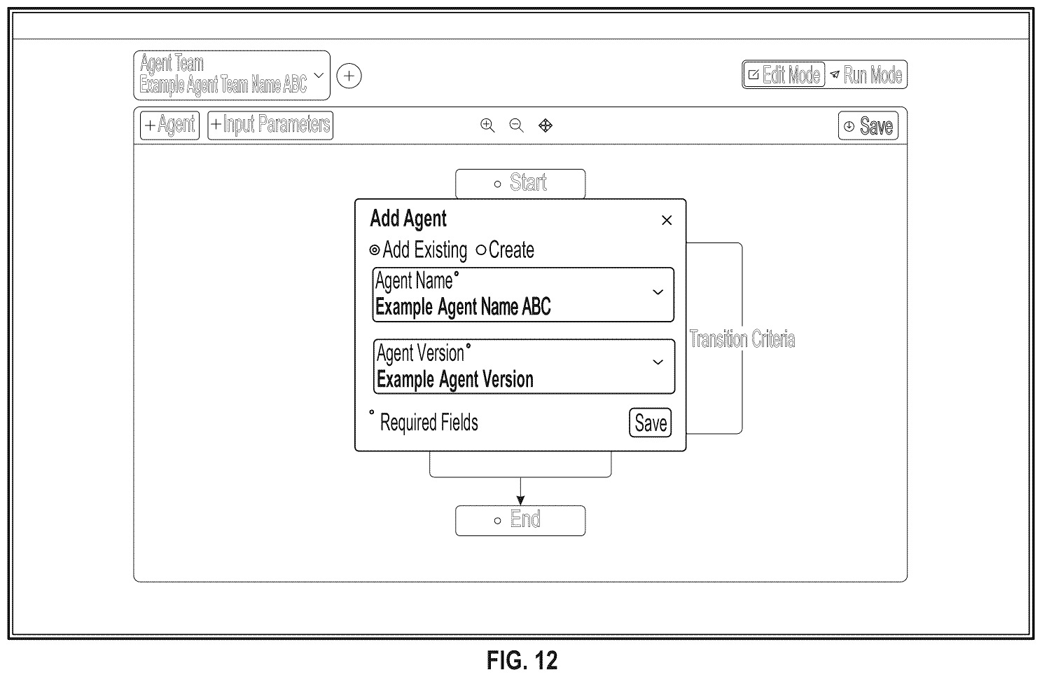

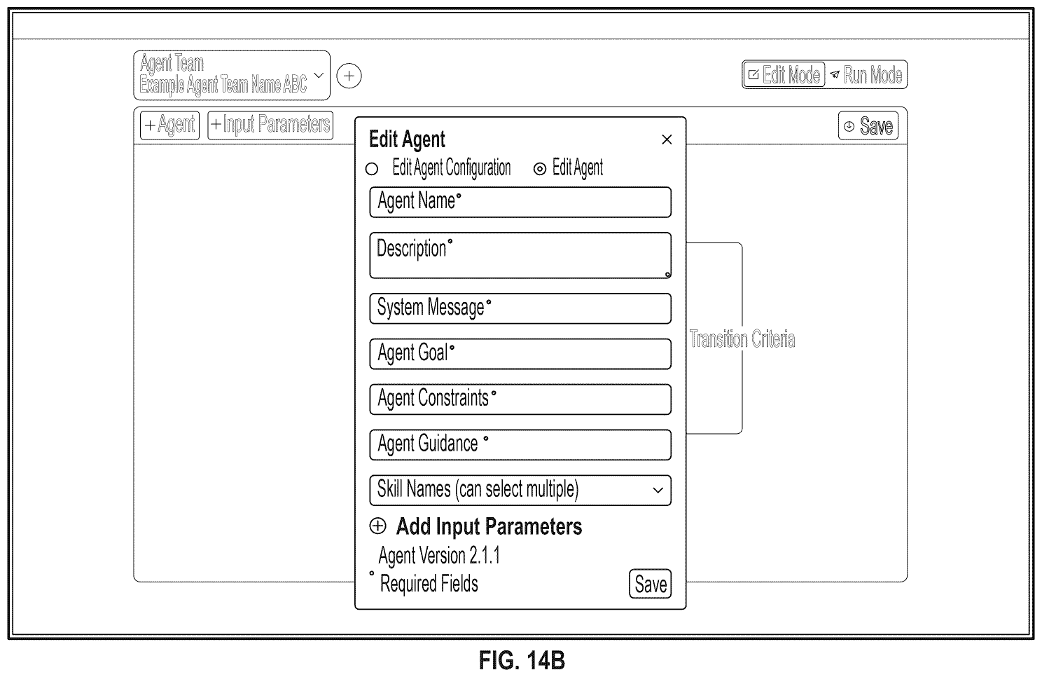

In the top left corner, a dropdown menu may be displayed, allowing the user to select from various pre-saved templates of AI agent teams. Various visual affordances may also be displayed to the user for creating a new AI agent, a new team of AI agents, and/or for configuring various input parameters, as will be described. FIG. 12 illustrates an agent creation interface that may be displayed in response to a user selection of a visual affordance for adding an AI agent to the team. In this interface, the user may be able to select from either adding an existing AI agent to a team of AI agents or creating an entirely new AI agent to be used by the operating system. In particular, FIG. 12 shows an interface for adding an existing AI agent to the team. The user may provide AI agent instructions in the form of natural language inputs into various fields to provide a name for the agent, an agent version, and custom instructions for configuring the agent such as goals, constraints, and guidance for how the AI agent should behave. AI agents may beneficially be saved in “versions” so that a user may select from a previously saved version of a particular AI agent, save a new version of the AI agent, or track changes made to the agent over time. FIG. 14A shows how these fields may be edited by the user at a later time through the user selecting a radio button option to “edit agent configuration” within an agent editing interface. This interface may be displayed to the user in response to the selection of a node corresponding to the particular agent, sub-team, starting state, or ending state to be edited in the displayed hierarchy of nodes.

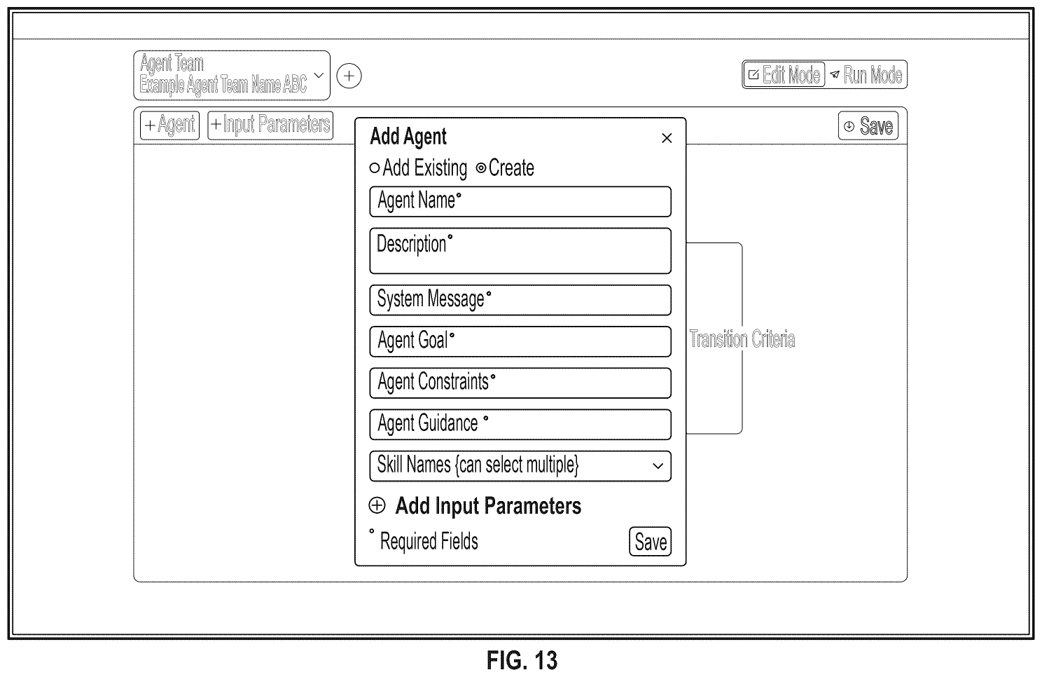

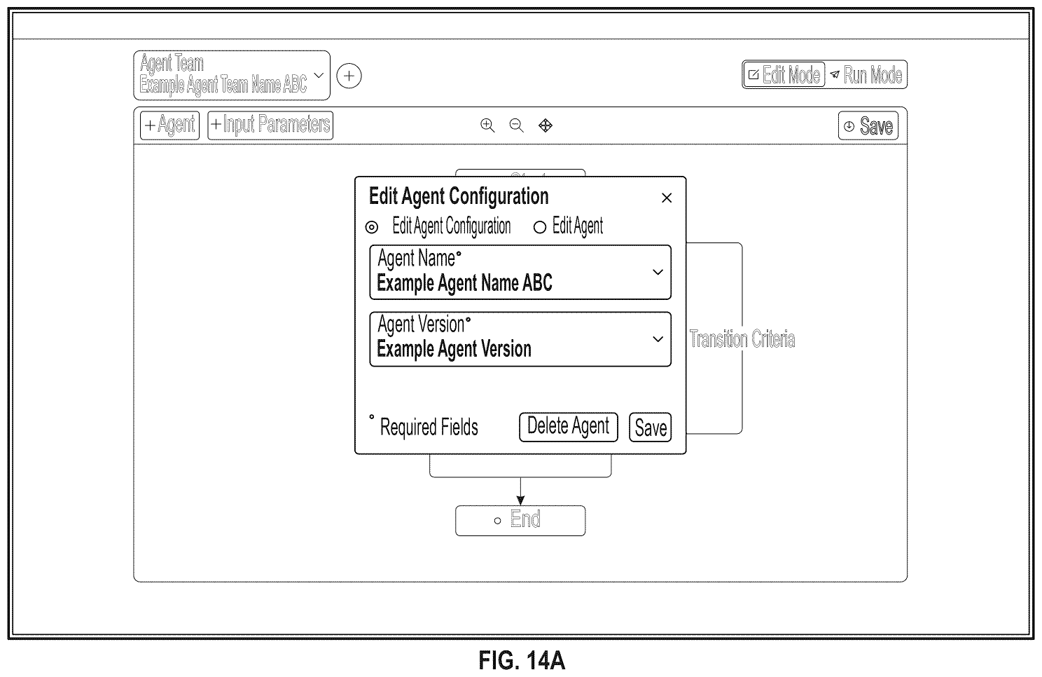

FIG. 13 shows an interface for creating a new AI agent. The user may provide natural language inputs into the various fields shown, for example, to add an agent name, an agent description, a system message, and AI agent instructions such as a goal, agent constraints, and agent guidance. Optionally, the user may select from a dropdown menu of skills to be utilized by the new AI agent. In some embodiments, the agent name and description may be used by the AI-based state manager to determine the next state of the operating system, along with the state transition criteria. The user may also be presented with an option for adding agent parameters, for example, a parameter name (e.g., a file, natural language, etc.) and a parameter type (e.g., a string, list, or file format) that can be displayed to the user at runtime for the user to input. The agent constraints field may allow the user to restrict which actions the agent is allowed to take. FIG. 14B shows how the user may edit one or more of the fields shown in FIG. 13 later in time through selecting a radio button option to “edit agent”in the agent editing interface.

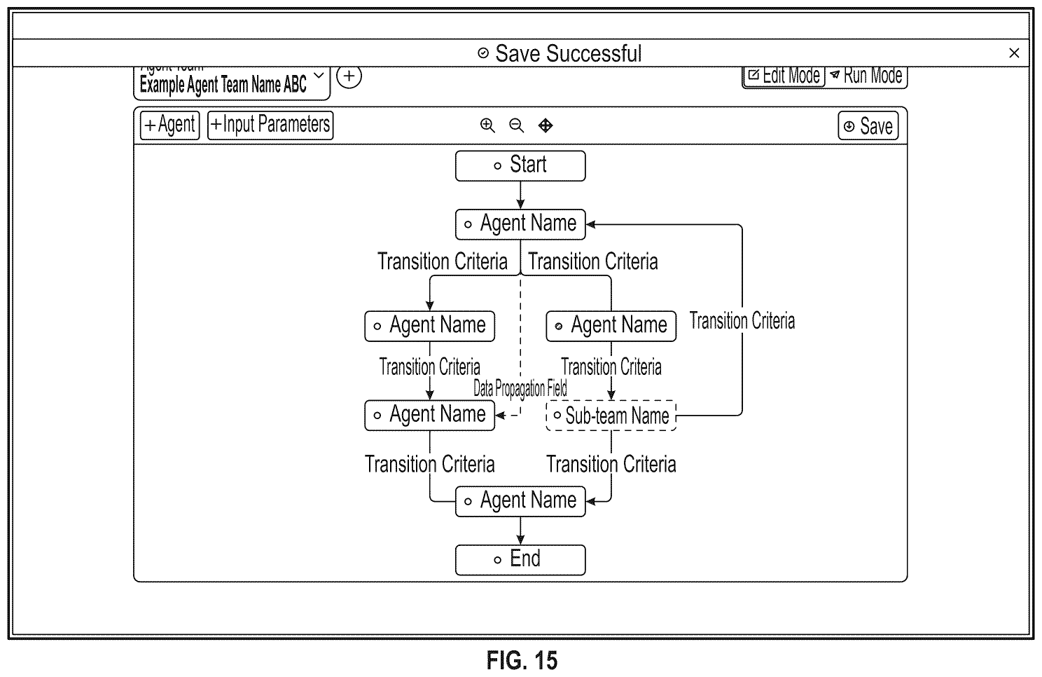

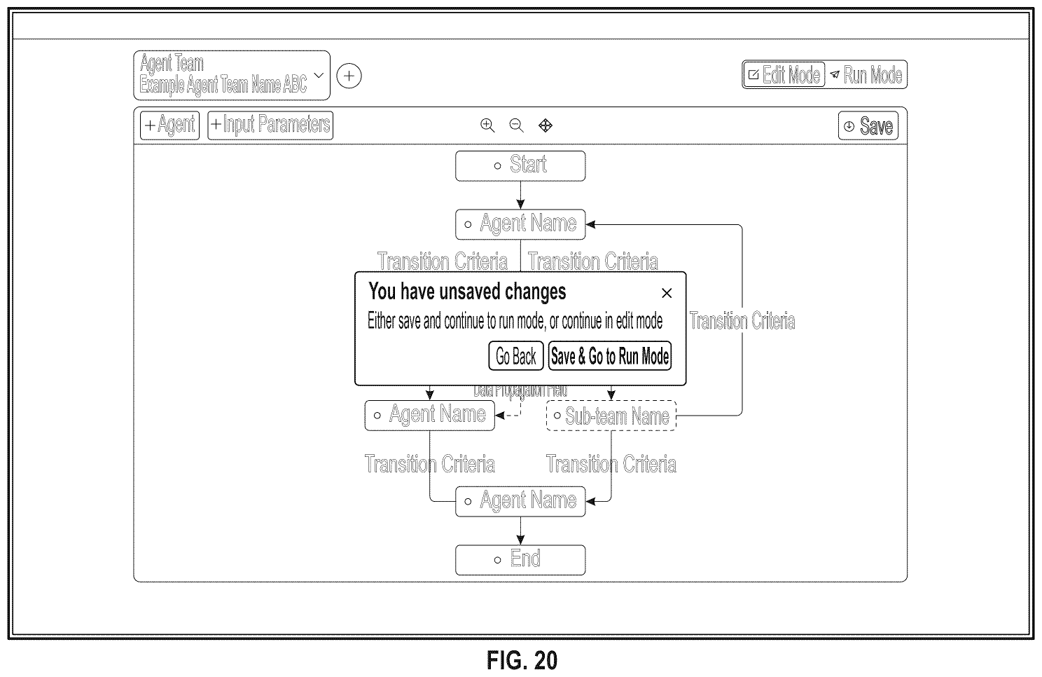

As shown in FIGS. 12-14B, a “save” button is displayed in the edit mode, and a user may need to select the save button in order for the instructions entered by the user in each field to be propagated into the memory of the AI-based state manager so that they can later be leveraged by the orchestrator during runtime. In these embodiments, as shown in FIG. 20, an alert may be displayed to the user if they attempt to exit the edit mode without saving their changes. If a save is successful, a message or banner may be displayed to the user indicating as such, as shown in FIG. 15. In other embodiments, the user interface may support an “autosave” functionality in which the user inputs may be propagated into the memory in real-time as they are provided by the user.

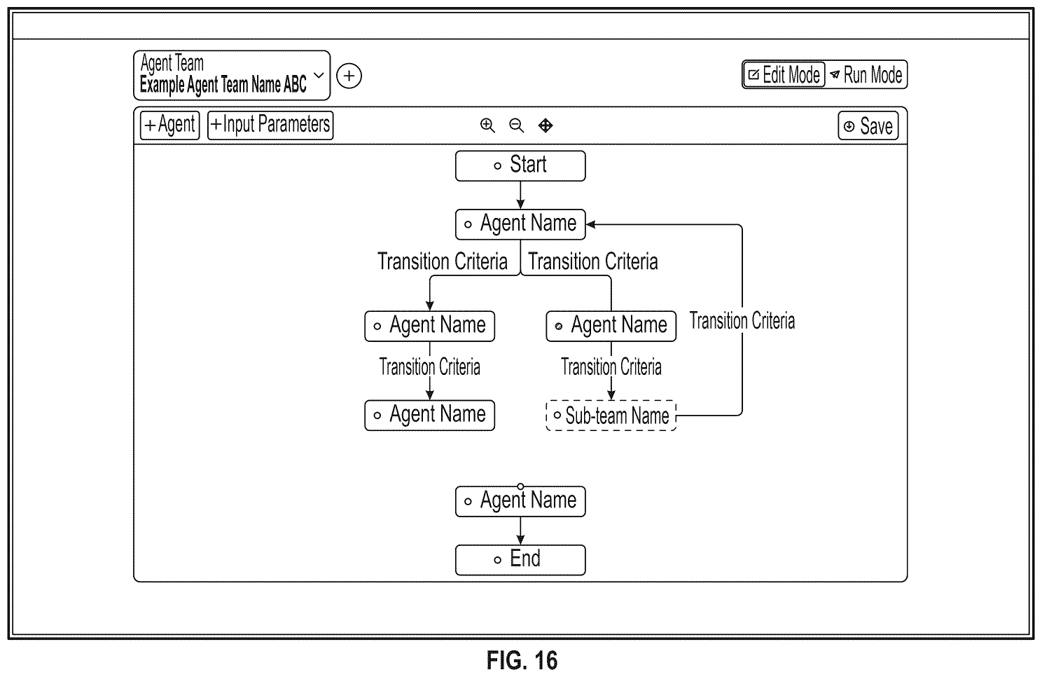

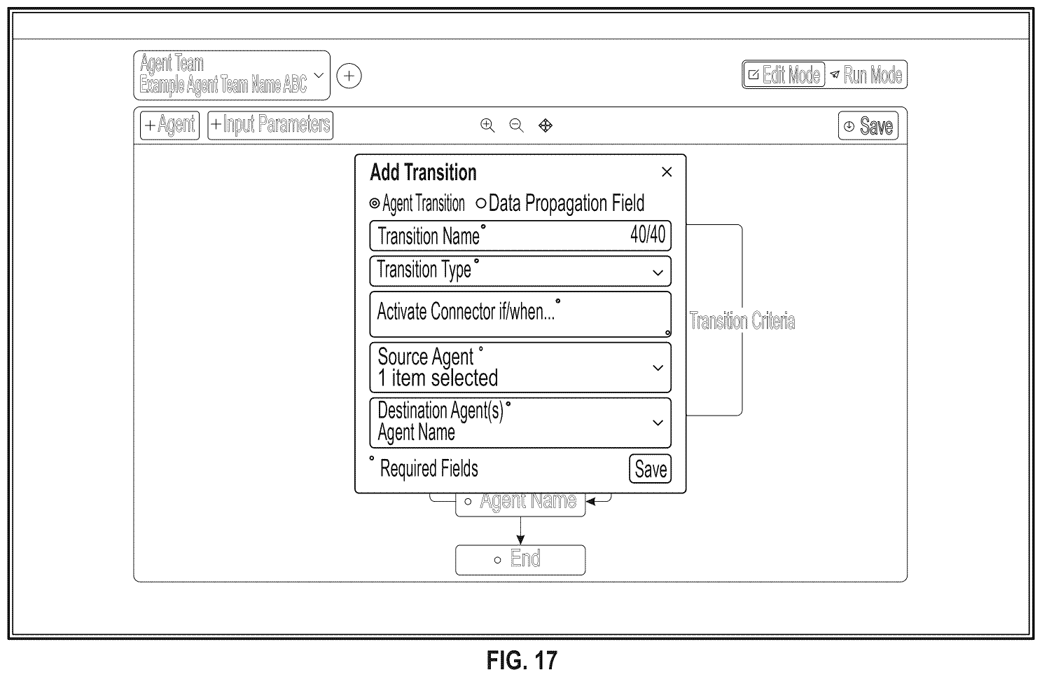

Referring to FIG. 16, an indicator may be displayed above an agent name on the border of the agent node if the node has not yet been connected by at least one edge. For example, the agent name shown on the bottom of the hierarchy has a circle on the border of the agent node, indicating that a transition to this agent has not yet been configured. The user may edit the transition criteria for an agent by selecting (e.g., double clicking or tapping) the edge leading up to the agent's node in the hierarchy. In response to the user's selection of the edge, a transition configuration interface may be displayed to the user, as shown in FIG. 17.

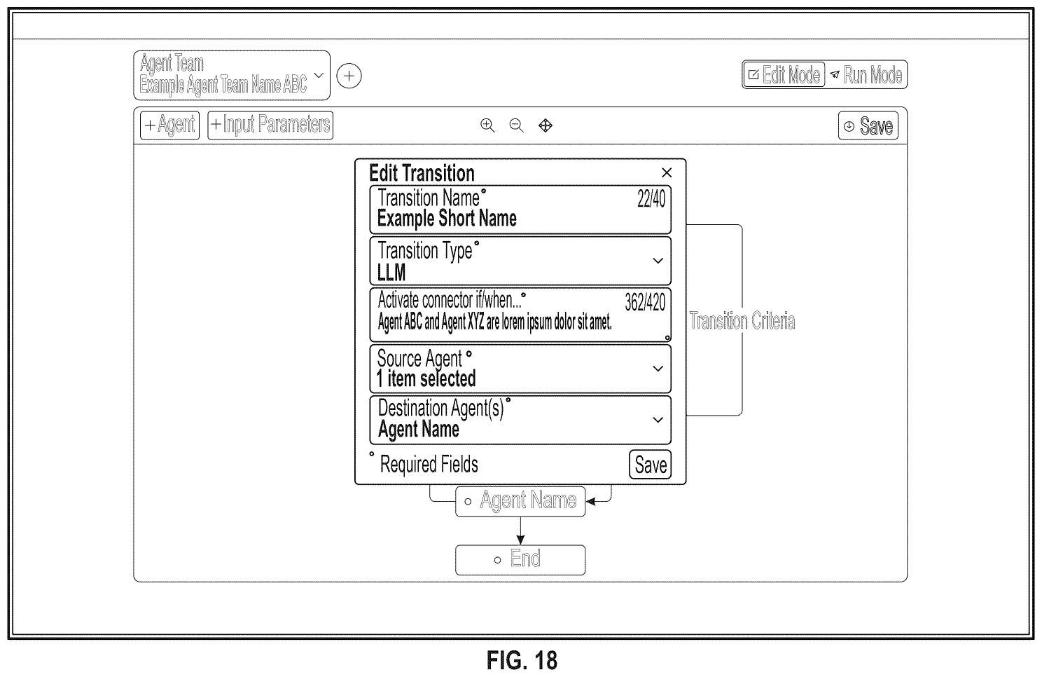

The transition configuration interface may include fields for the user to input a transition name, a transition type (e.g., natural language, coding language, etc.), and transition criteria. As mentioned above, the use of an LLM embedded within the state manager allows for the user to provide transition criteria in natural language form. For example, in the “Activate connector if/when...” field, the user may simply input their desired state transition criteria as natural language (e.g., by typing “transition to this state if the code is validated. ”) The state transition criteria may be inputted in other forms, such as in traditional code if the user desires. The user may specify a source agent and the destination agents that are to be invoked once the criteria for transitioning from the source agent has been satisfied. A user may optionally add/edit one or more data propagation fields within the transition configuration interface. This feature may allow the user to select the source agent, destination agent(s), and the output field from the source agent. As with the AI agents, the user may be able to edit existing state transition criteria by selecting the desired edge, after which a transition editing interface, shown in FIG. 18, may be displayed.

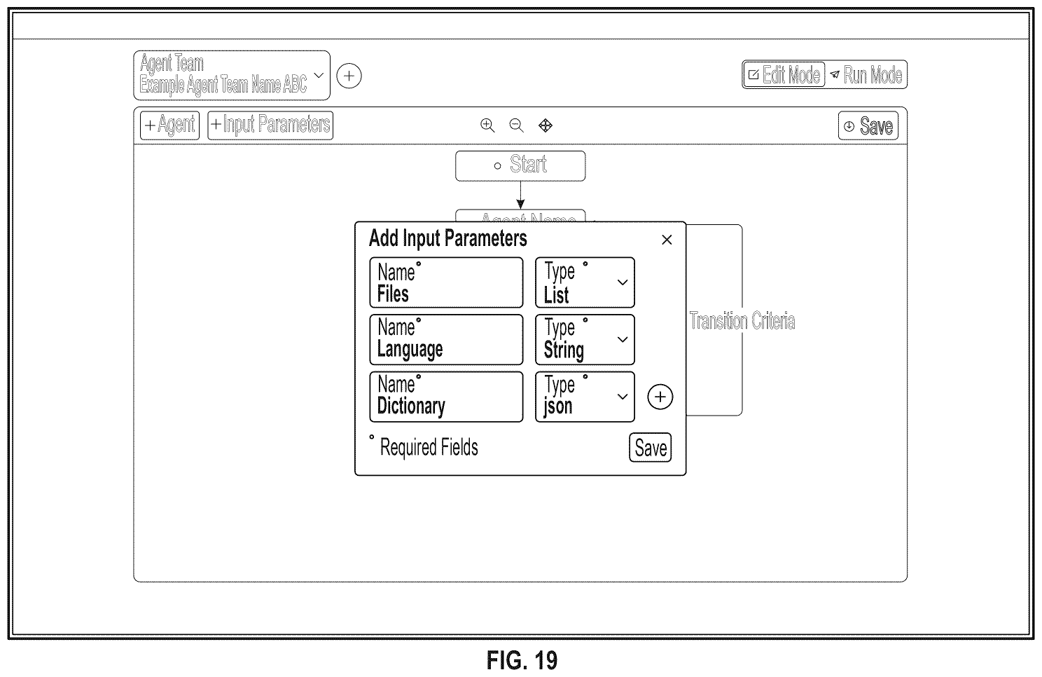

Referring to FIG. 19, the user may be able to add various input parameter fields by selecting a visual affordance, e.g., displayed in the corner of the edit mode interface. The input parameter fields may allow the user to customize program executions when running the operating system by specifying an input name and type for inputs provided to the operating system. For example, parameters are included within agent/team configurations. The user can include these parameters as prompts by wrapping the parameter name in braces (e.g. {param-name}). In this example, {param-name} would be updated to “param value” if the user assigns “param value” as the value of “param-name” within the user interface. The user will need to provide the inputs specified by these input parameter fields in order to run the operating system.

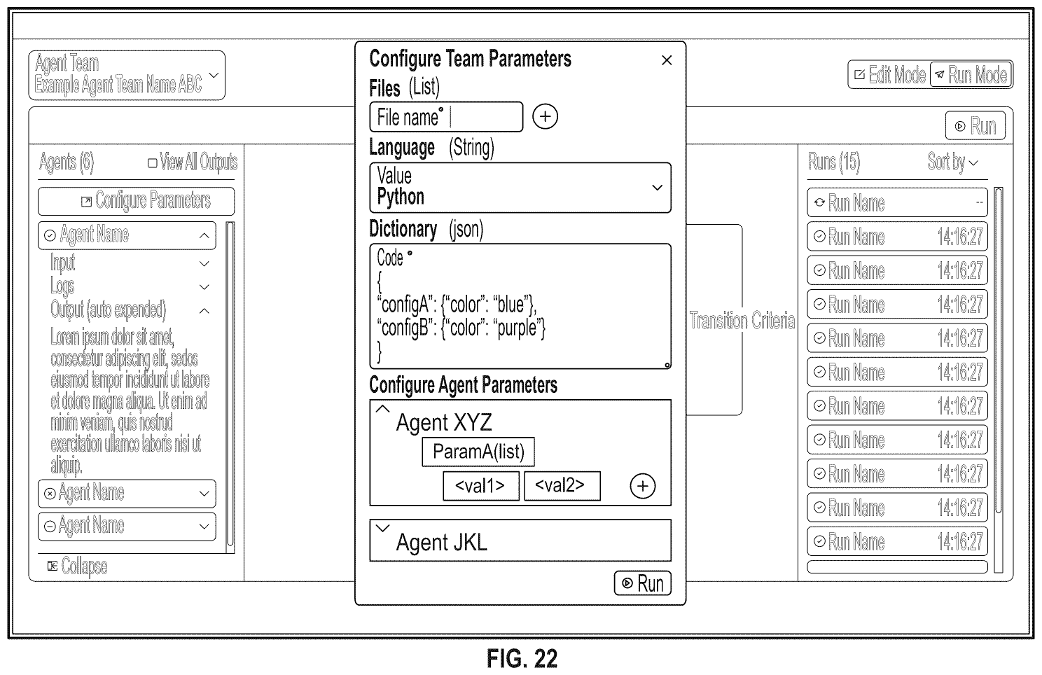

Once the user is satisfied with the configuration of the operating system, the user may select a visual affordance for switching to the “run mode” of the user interface. Selecting the visual affordance a first time may cause the display of the input parameter interface shown in FIG. 22. As shown in FIG. 22, when a user executes a new run, they may need to provide the inputs in the fields and formats that were configured in the manner described with respect to FIGS. 13 and 19. The user may also have the option to edit agent-level parameters prior to executing a new run. As shown in FIG. 22, depending on the number of agents in the team and the types of parameters for each agent (e.g., list, string, etc.), the user may be presented with headings for each agent and parameter, and the user input may be limited based on the specified parameter type. For example, if parameter A of agent XYZ has a “list” parameter type, the user may be able to assign multiple values to that parameter. In contrast, if parameter A had a “string” parameter type, the user may only be able to assign a single value to that parameter.

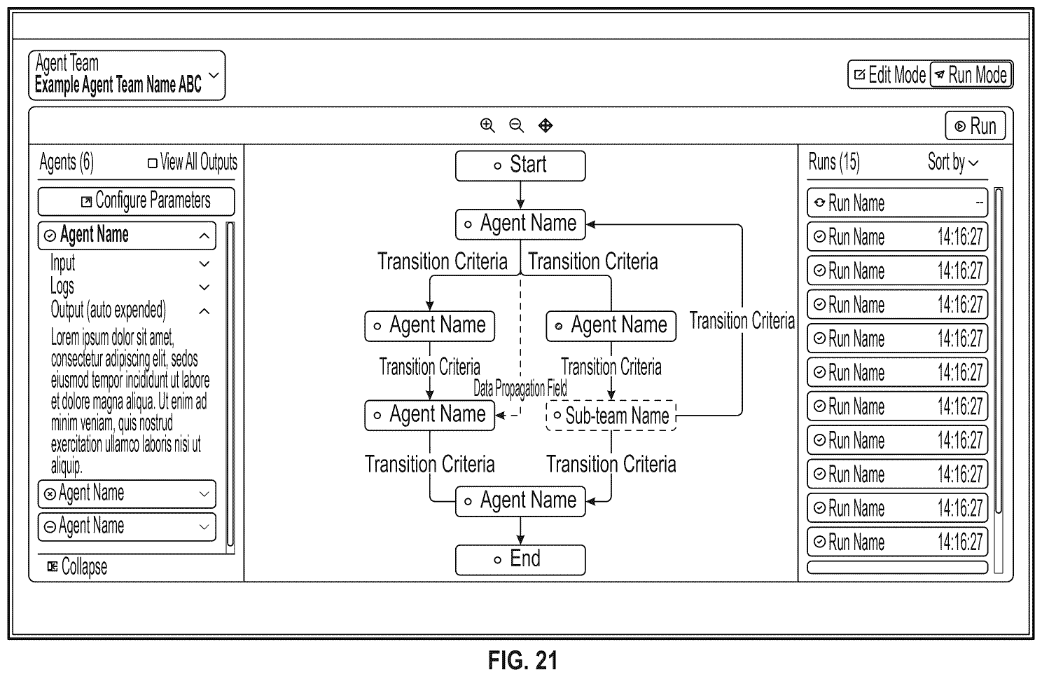

Once the user has inputted the team-and agent-level parameters, the user may select a visual affordance for executing a program run a second time (e.g., the “run” button may be displayed a second time within the input parameter interface shown in FIG. 22). Then, an execution request may be sent to the orchestrator to begin the program run. In some embodiments, the execution request can go through a request handler/queuing system before it is sent to the orchestrator. As shown in FIG. 21, the run mode may display a log, or history, of AI agent/team activity, the hierarchy of nodes and edges representing the AI agents/sub-teams and transitions, and a list of active and completed program runs.

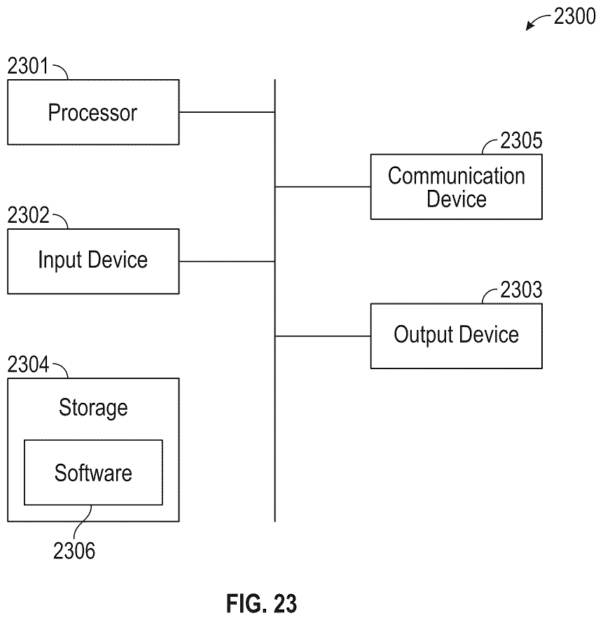

FIG. 23 depicts parts of a computer, in accordance with various embodiments. Computer 2300 can be a component of an AI-based operating system as described herein, may host one or more components of the operating system, and/or may carry out part or all of the computer-implemented methods described herein. Computer 2300 may also be used for displaying the user interface described herein and/or configuring the AI-based operating system described herein. Computer 2300 can be a host computer connected to a network. Computer 900 can be a client computer or a server. As shown in FIG. 23, computer 2300 can be any suitable type of microprocessor-based device, such as a personal computer, workstation, server, videogame console, or handheld computing device, such as a phone or tablet. The computer can include, for example, one or more of processor 2301, computer input device 2302, output device 2303, storage 2304, and communication device 2305. Computer input device 2302 can generally correspond to those described above and can either be connectable or integrated with the computer.

Computer input device 2302 can be any suitable device that provides input, such as a touch screen or monitor, keyboard, mouse, or voice-recognition device. Output device 2303 can be any suitable device that provides output, such as a touch screen, monitor, printer, disk drive, or speaker.

Storage 2304 can be any suitable device that provides storage, such as an electrical, magnetic, or optical memory, including a RAM, cache, hard drive, CD-ROM drive, tape drive, removable storage disk, or other non-transitory computer readable medium. Storage 1304 can include one storage device or more than one storage device. As used herein, the terms storage, memory, and/or storage medium/media may refer to singular and/or plural devices which may store data and/or code/instructions individually, redundantly, and/or in cooperation with one another, for example in a local and/or cloud storage environment. Communication device 2305 can include any suitable device capable of transmitting and receiving signals over a network, such as a network interface chip or card. The components of the computer can be connected in any suitable manner, such as via a physical bus or wirelessly. Storage 2304 can be a non-transitory computer-readable storage medium comprising one or more programs, which, when executed by one or more processors, such as processor 2301, cause the one or more processors to execute methods described herein.

Software 2306, which can be stored in storage 2304 and executed by processor 2301, can include, for example, the programming that embodies the functionality of the present disclosure (e.g., as embodied in the systems, computers, servers, and/or devices as described above). In some embodiments, software 2306 can be implemented and executed on a combination of servers such as application servers and database servers.

Software 2306, or part thereof, can also be stored and/or transported within any computer-readable storage medium for use by or in connection with an instruction execution system, apparatus, or device, such as those described above, that can fetch and execute instructions associated with the software from the instruction execution system, apparatus, or device. In the context of this disclosure, a computer-readable storage medium can be any medium, such as storage 2304, that can contain or store programming for use by or in connection with an instruction execution system, apparatus, or device.

Software 2306 can also be propagated within any transport medium for use by or in connection with an instruction execution system, apparatus, or device, such as those described above, that can fetch and execute instructions associated with the software from the instruction execution system, apparatus, or device. In the context of this disclosure, a transport medium can be any medium that can communicate, propagate, or transport programming for use by or in connection with an instruction execution system, apparatus, or device. The transport-readable medium can include, but is not limited to, an electronic, magnetic, optical, electromagnetic, or infrared wired or wireless propagation medium.

Computer 2300 may be connected to a network, which can be any suitable type of interconnected communication system. The network can implement any suitable communications protocol and can be secured by any suitable security protocol. The network can comprise network links of any suitable arrangement that can implement the transmission and reception of network signals, such as wireless network connections, T1 or T3 lines, cable networks, DSL, or telephone lines.

Computer 2300 can implement any operating system suitable for operating the network. Software 2306 can be written in any suitable programming language, such as C, C++, Java, or Python. In various embodiments, application software embodying the functionality of the present disclosure can be deployed in different configurations, such as in a client/server arrangement or through a web browser as a Web-based application or Web service, for example.

1. A computer-implemented method comprising:
storing, in memory of an AI-based state manager of an operating system, state transition instructions for transitioning states of the operating system;
receiving, by an orchestrator of the AI-based state manager, an execution request;
retrieving, by the orchestrator, from the memory, state transition instructions for an AI model of the AI-based state manager based on the execution request;
providing, by the orchestrator, to the AI model, an AI model input comprising the retrieved state transition instructions;
determining, by the AI model, an AI model output based on the AI model input; and
applying, by the orchestrator, based at least in part on the AI model output, a state transition to the operating system by invoking one or more downstream systems.

2. The computer-implemented method of claim 1, wherein the AI model is a language model.

3. The computer-implemented method of claim 2, wherein the state transition instructions comprise natural language.

4. The computer-implemented method of claim 1, wherein the one or more downstream systems comprise one or more AI agents.

5. The computer-implemented method of claim 4, wherein each of the one or more AI agents are configured to perform a single task.

6. The computer-implemented method of claim 4, wherein the one or more AI agents comprise a planner agent team, and wherein the computer-implemented method comprises generating a plan for carrying out the execution request by recursively invoking the planner agent team.

7. The computer-implemented method of claim 4, further comprising:
searching, by the orchestrator, based at least in part on the execution request, a repository of tools to be employed by the one or more AI agents;
retrieving, by the orchestrator, based at least in part on the execution request, a tool from the repository of tools; and
routing, by the orchestrator, the tool to the one or more AI agents.

8. The computer-implemented method of claim 7, wherein the repository of tools comprises a vector database, and wherein searching, by the orchestrator, based at least in part on the execution request comprises using a vector search algorithm.

9. The computer-implemented method of claim 7, wherein the repository of tools comprises a knowledge graph, and wherein searching, by the orchestrator, based at least in part on the execution request comprises using a knowledge graph search algorithm.

10. The computer-implemented method of claim 4, wherein the one or more AI agents comprise one or more teams of AI agents.

11. The computer-implemented method of claim 10, wherein the one or more teams of AI agents comprise one or more sub-teams of AI agents.

12. The computer-implemented method of claim 1, further comprising:
receiving, by the orchestrator, one or more outputs from the one or more downstream systems; and
providing, by the orchestrator, to the AI model, an AI model input based at least in part on the one or more outputs from the one or more downstream systems.

13. The computer-implemented method of claim 1, wherein the one or more downstream systems are part of the operating system.

14. The computer-implemented method of claim 1, wherein the one or more downstream systems are part of a second AI-based operating system.

15. A computer-implemented method for configuring an AI-based operating system comprising:
displaying an interface for configuring the AI-based operating system, the interface comprising:
one or more visual affordances, each representing an AI agent of the AI-based operating system, and
a visual affordance for executing a program on the AI-based operating system;
receiving, via the interface for configuring the AI-based operating system, a user selection of a visual affordance representing an AI agent of the AI-based operating system;
displaying, in response to the user selection of the visual affordance representing the AI agent, an interface for configuring the AI agent;
receiving, via the interface for configuring the AI agent, a user input comprising AI agent instructions and a selection of the visual affordance for executing a program by the AI-based operating system;
configuring, by an orchestrator of the AI-based operating system, the AI agent based on the AI agent instructions; and
executing, via the AI-based operating system, at least a portion of a program using the configured AI agent.

16. The computer-implemented method of claim 15, wherein the user input comprises one or more of an agent name, an agent type, or an agent version.

17. The computer-implemented method of claim 15, wherein the one or more visual affordances are displayed as a hierarchy of nodes, the hierarchy of nodes representing a team of AI agents of the AI-based operating system.

18. The computer-implemented method of claim 17, each node representing an AI agent sub-team within the team of one or more AI agents.

19. The computer-implemented method of claim 17, wherein the nodes in the displayed hierarchy of nodes are connected by edges, each edge representing transition criteria for transitioning between AI agents.

20. The computer-implemented method of claim 15, wherein the interface for configuring the AI-based operating system comprises a visual affordance for configuring a transition between different AI agents, and wherein the computer-implemented method comprises:
receiving, via the interface for configuring the AI-based operating system, a user selection of the visual affordance for configuring the transition between different AI agents,
displaying, in response to the user selection of the visual affordance for configuring the transition between different AI agents, a transition configuration interface;
receiving, via the transition configuration interface, a user input comprising state transition instructions for transitioning between different AI agents; and
generating, by the orchestrator, for an AI model of the AI-based operating system, an AI model input comprising the state transition instructions.

21. The computer-implemented method of claim 15, further comprising:
displaying, in response to receiving the selection of the visual affordance for executing a program by the AI-based operating system, a run interface comprising a log of AI agent activity and a list of active and completed program executions of the AI-based operating system.

22. The computer-implemented method of claim 15, wherein the interface for configuring the AI-based operating system comprises a visual affordance for adding an AI agent to the AI-based operating system.

23. The computer-implemented method of claim 15, wherein the AI agent instructions comprise natural language.

24. A non-transitory computer-readable storage medium storing one or more programs, the one or more programs comprising instructions which, when executed by a system comprising one or more processors and an operating system comprising an AI-based state manager, cause the system to:
store, in memory of an AI-based state manager of an operating system, state transition instructions for transitioning states of the operating system;
receive, by an orchestrator of the AI-based state manager, an execution request;
retrieve, by the orchestrator, from the memory, state transition instructions for an AI model of the AI-based state manager based on the execution request;
provide, by the orchestrator, to the AI model, an AI model input comprising the retrieved state transition instructions;
determine, by the AI model, an AI model output based on the AI model input; and
apply, by the orchestrator, based at least in part on the AI model output, a state transition to the operating system by invoking one or more downstream systems.
